(19) United States
(12) Patent Application Publication
(10) Pub. No.: US 2019/0348614 A1
(43) Pub. Date: Nov. 14, 2019

(54) ELECTRON TRANSPORTING LAYERS, ORGANIC ELECTROLUMINESCENCE DEVICES, AND DISPLAYS

(71) Applicants: Kunshan Go-Visionox Opto-Electronics Co., Ltd., Kunshan (CN); TSINGHUA UNIVERSITY, Beijing (CN)

(72) Inventors: Lian DUAN, Kunshan (CN); Zhengyang BIN, Kunshan (CN); Guomeng LI, Kunshan (CN)

(21) Appl. No.: 16/521,570

(22) Filed: Jul. 24, 2019

Related U.S. Application Data
(63) Continuation of application No. PCT/CN2018/089977, filed on Jun. 5, 2018.

(30) Foreign Application Priority Data
Dec. 29, 2017 (CN) 201711480627.1

(51) Int. Cl. H01L 51/00

(52) U.S. Cl. CPC H01L 51/0067; H01L 51/0069; H01L 51/0072; H01L 51/5076; H01L 51/0073; H01L 51/0054; H01L 51/0074

(57) ABSTRACT

An electron transporting layer is provided. A raw material of the electron transporting layer includes an inert metal and an organic compound capable of performing coordination reaction with the inert metal. The organic compound has the following formula: Ar₁L₁-Ar₂ₘ-L₂-Ar₃. L1 and L2 are respectively independently selected from the group consisting of an alkylene group containing 1 to 12 carbon atoms and an arylene group containing 6 to 30 carbon atoms. Ar1, Ar2, and Ar3 are respectively independently selected from the group consisting of a nitrogen-oxygen coordination group, a nitrogen-sulfur coordination group, a sulfur-oxygen coordination group, a sulfur-sulfur coordination group, an oxygen-oxygen coordination group, and a nitrogen-nitrogen coordination group; and m is an integer from 0 to 10.

### CROSS-REFERENCE TO RELATED APPLICATIONS

This application is a continuation application of International Application No. PCT/CN2018/089977, filed on Jun. 5, 2018, entitled “ELECTRON TRANSPORTING LAYERS, ORGANIC ELECTROLUMINESCENCE DEVICES, AND DISPLAYS”, which claims priority to Chinese Patent Application No. 201711480627.1, filed on Dec. 29, 2017, both of which are incorporated by reference herein for all purposes.

### TECHNICAL FIELD

Exemplary embodiments of the present disclosure relate to the field of organic electroluminescence devices.

### BACKGROUND TECHNOLOGY

Organic electroluminescence devices, such as organic light-emitting diodes (OLEDs), have become the main force of next-generation display technology due to a series of advantages such as self-luminescence, low power consumption, large viewing angle, high response speed, light and thin.

The luminous efficiency of an organic electroluminescence device depends not only on the luminous efficiency of the luminescence material itself, but also on the transporting of carriers within the transporting layer and the luminescence layer. The imbalance between electron and hole injection is one of the factors affecting the luminous efficiency. Compared with the hole injection transporting capability, the electron injection transporting capability of organic molecules is weak, the imbalance between the electron and hole injection and the difference in mobility make carriers injected from the two electrodes unable to be effectively limited in a luminescence region to form excitons, resulting in a part of excess carriers reaching the electrode, causing quenching of light emission at the electrode. In addition, the excess carriers also collide with the triplet energy level of the excitons in the luminescence layer, resulting in triplet-polaron annihilation (TPA), which causes a decrease in the luminous efficiency and lifetime of the electroluminescence device.

Compared with inorganic semiconductors, organic semiconductor materials have lower intermolecular force, and carriers are mainly transported by hopping, resulting in lower mobility and conductivity of the transporting layer. At present, the electron transporting layer has a low electron mobility (on the order of about 10⁻⁵ cm² V⁻¹ s⁻¹ to 10⁻⁴ cm² V⁻¹ s⁻¹), resulting in a low luminous efficiency of the organic electroluminescence device.

### SUMMARY

Accordingly, it is desirable to provide an electron transporting layer having high electron mobility.

In addition, an organic electroluminescence device and a display are also provided.

An electron transporting layer is provided. A raw material of the electron transporting layer includes an inert metal and an organic compound capable of performing coordination reaction with the inert metal. The organic compound has the following formula:

Ar₁L₁-Ar₂ₘ-L₂-Ar₃

L₁ and L₂ are respectively independently selected from the group consisting of an alkylene group containing 1 to 12 carbon atoms and an arylene group containing 6 to 30 carbon atoms; Ar₁, Ar₂, and Ar₃ are respectively independently selected from the group consisting of a nitrogen-oxygen coordination group, a nitrogen-sulfur coordination group, a sulfur-oxygen coordination group, a sulfur-sulfur coordination group, an oxygen-oxygen coordination group, and a nitrogen-nitrogen coordination group; and m is an integer from 0 to 10.

An organic electroluminescence device includes the aforementioned electron transporting layer.

A display includes the aforementioned organic electroluminescence device.

The details of one or more embodiments of the disclosure are set forth in the accompanying drawings and the description below. Other features, objects, and advantages of the disclosure will be apparent from the description and drawings, and from the claims.

### BRIEF DESCRIPTION OF THE DRAWINGS

FIG. 1 is a schematic view of a TOF (Time of flight) device according to an embodiment;

FIG. 2 is a schematic view of a single carrier device according to an embodiment;

FIG. 3 is a schematic view of an organic electroluminescence device according to an embodiment;

FIG. 4 is a graph showing temperature-carrier mobility test of TOF devices of Example 1 and Comparative Example 1;

FIG. 5 is a graph showing current density-voltage test of single carrier devices of Examples 12 to 14, Comparative Example 4, and Comparative Example 5; and

FIG. 6 is a graph showing current density-voltage test of single carrier devices of Examples 14 and 15.

### DETAILED DESCRIPTION OF THE EMBODIMENTS

In order to facilitate the understanding of the present disclosure, embodiments of the disclosure are described more fully hereinafter with reference to the accompanying drawings. The various embodiments of the disclosure may, however, be embodied in many different forms and should not be construed as limited to the embodiments set forth herein. Rather, these embodiments are provided so that this disclosure will be thorough and complete, and will fully convey the scope of the disclosure to those skilled in the art.

Unless otherwise defined, all terms (including technical and scientific terms) used herein have the same meaning as commonly understood by one of ordinary skill in the art to which this disclosure belongs. The terms used herein in the specification of the present disclosure are for the purpose of describing specific embodiments only and are not intended to limit the present disclosure.

An electron transporting layer according to an embodiment is prepared from a raw material of the electron transporting layer, and the raw material of the electron transporting layer includes an inert metal and an organic compound capable of performing coordination reaction with the inert metal. The organic compound has the following formula:

Ar₁L₁-Ar₂ₘ-L₂-Ar₃

L₁ and L₂ are respectively independently selected from the group consisting of an alkylene group containing 1 to 12 carbon atoms and an arylene group containing 6 to 30 carbon atoms; Ar₁, Ar₂, and Ar₃ are respectively independently selected from the group consisting of a nitrogen-oxygen coordination group, a nitrogen-sulfur coordination group, a sulfur-oxygen coordination group, a sulfur-sulfur coordination group, an oxygen-oxygen coordination group, and a nitrogen-nitrogen coordination group; and m is an integer from 0 to 10.

In addition, each of Ar₁, Ar₂, and Ar₃ is independently selected from the group consisting of the following structures:

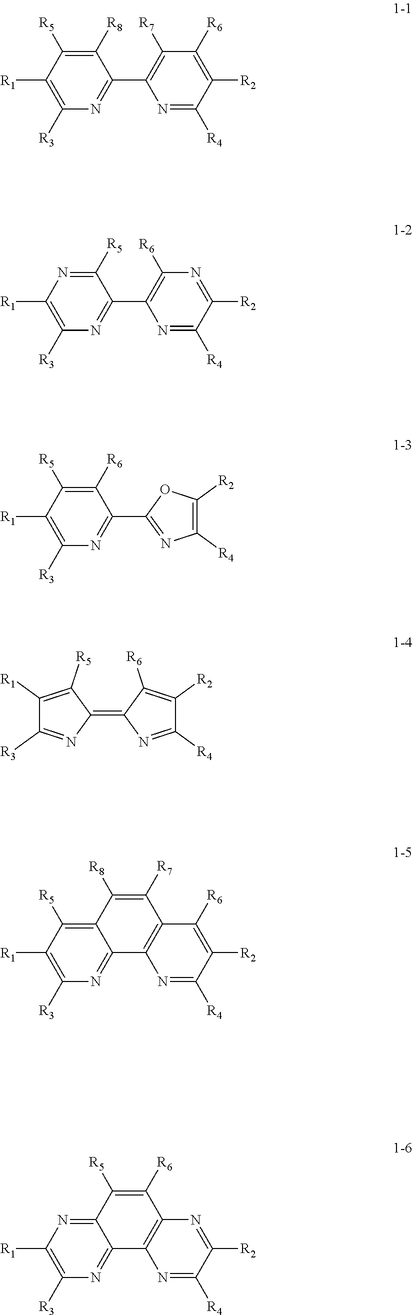

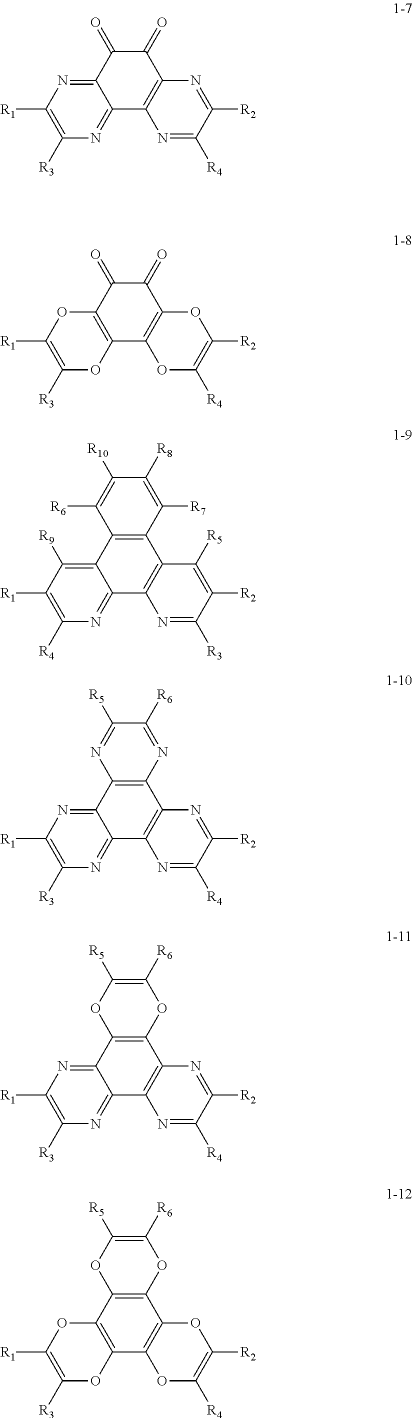

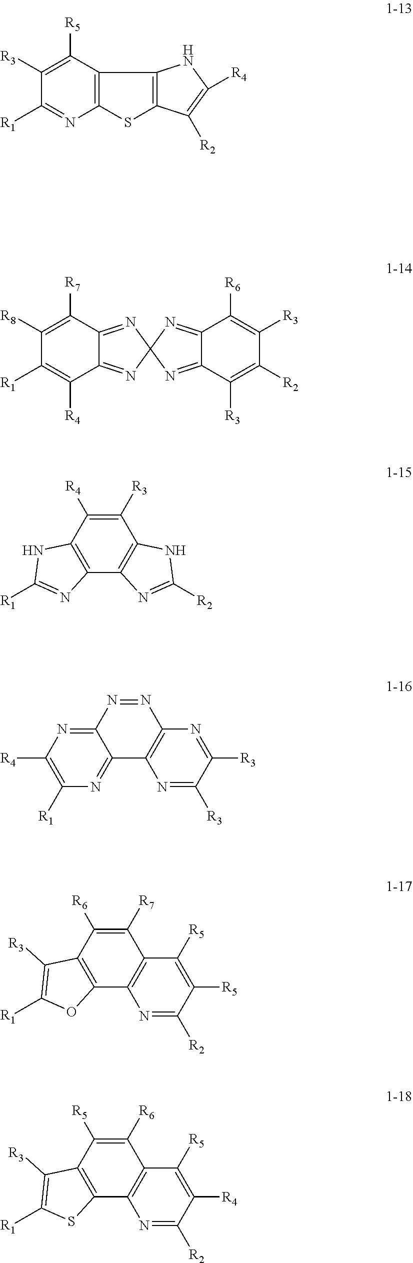

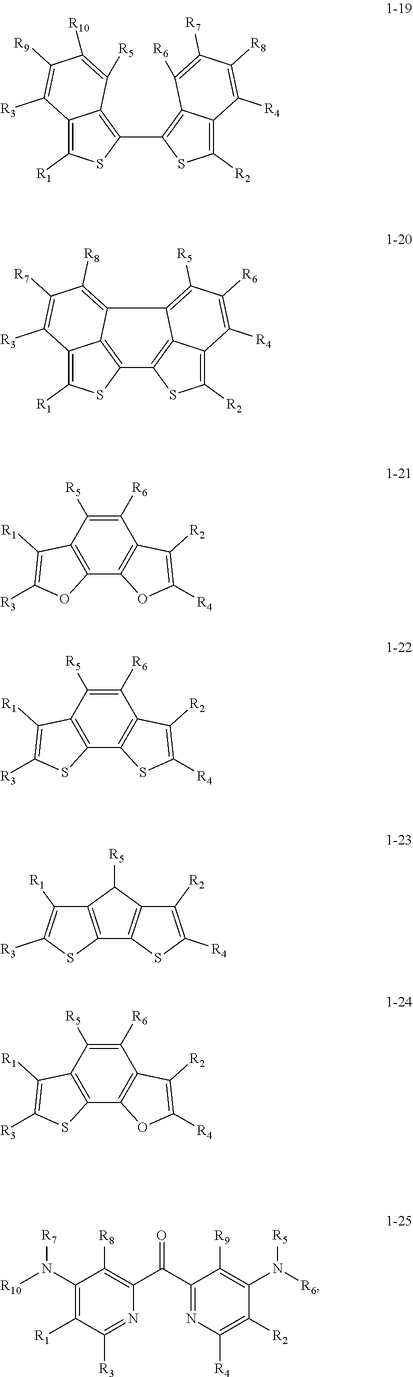

each of R₁, R₂, R₃, R₄, R₅, R₆, R₇, R₈, R₉, and R₁₀ is selected from the group consisting of a hydrogen atom, an alkyl group, an aryl group, a conjugated heterocyclic ring, a methoxy group, an amino group, —CₙH₂ₙ—NH₂, a cyano group, a halogen atom, a haloalkyl group, an aldehyde group, a keto group, an ester group, an acetylacetonate group, —CₙH₂ₙ—CN, —CₙH₂ₙ—COOR, —CₙH₂ₙ—CHO, and —CₙH₂ₙ—COCH₂COR, in which the conjugated heterocyclic ring is mainly a nitrogen-containing heterocyclic ring, a sulfur-containing heterocyclic ring, and an oxygen-containing heterocyclic ring; R is selected from the group consisting of a hydrogen atom, an alkyl group containing 1 to 10 carbon atoms, and an aryl group containing 6 to 18 carbon atoms; and n is an integer from 1 to 30. In addition, the aryl group is a phenyl group.

All sites in the aforementioned Ar₁ structure can be linked to L₁, all sites in the aforementioned Ar₂ structure can be linked to L₁ and L₂, and all sites in the aforementioned Ar₃ structure can be linked to L₂. In addition, the R₁, R₂, R₃, and R₄ sites in the aforementioned Ar₁ are sites to which L₁ is linked, the R₁, R₂, R₃, and R₄ sites in the aforementioned Ar₂ are sites to which L₁ and L₂ are linked, and the R₁, R₂, R₃, and R₄ sites in the aforementioned Ar₃ are sites to which L₂ is linked.

Moreover, the L₁ and the L₂ are respectively independently selected from the group consisting of the following structures:

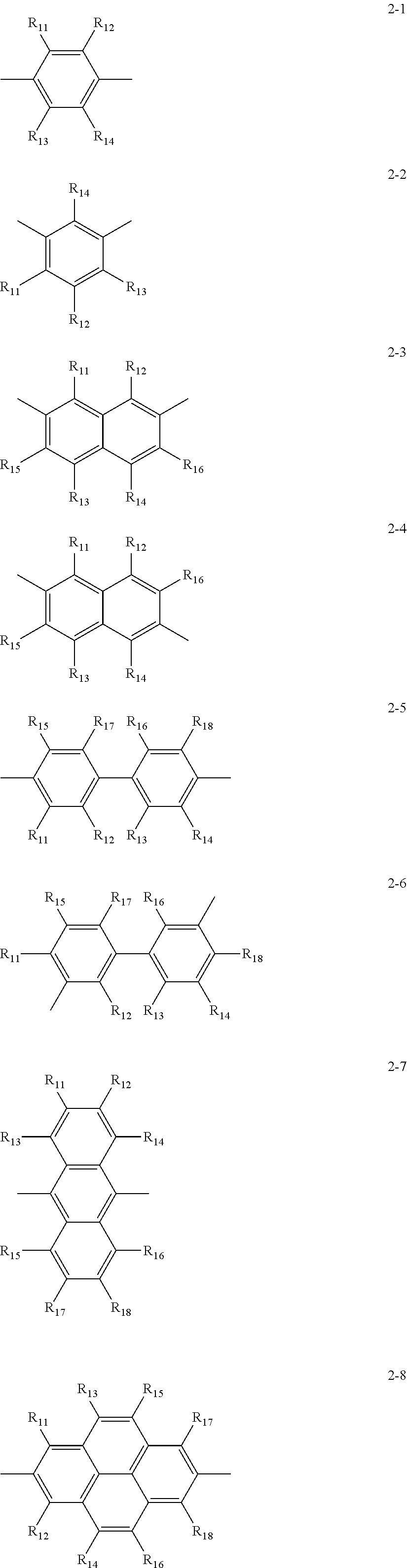

each of R₁₁, R₁₂, R₁₃, R₁₄, R₁₅, R₁₆, R₁₇, and R₁₈ is selected from the group consisting of a hydrogen atom, an alkyl group, a methoxy group, an amino group, —CₙH₂ₙ—NH₂, a cyano group, a halogen atom, a haloalkyl group, an aldehyde group, a keto group, an ester group, and an acetylacetonate group.

Specifically, the organic compound is selected from the group consisting of the following structures:

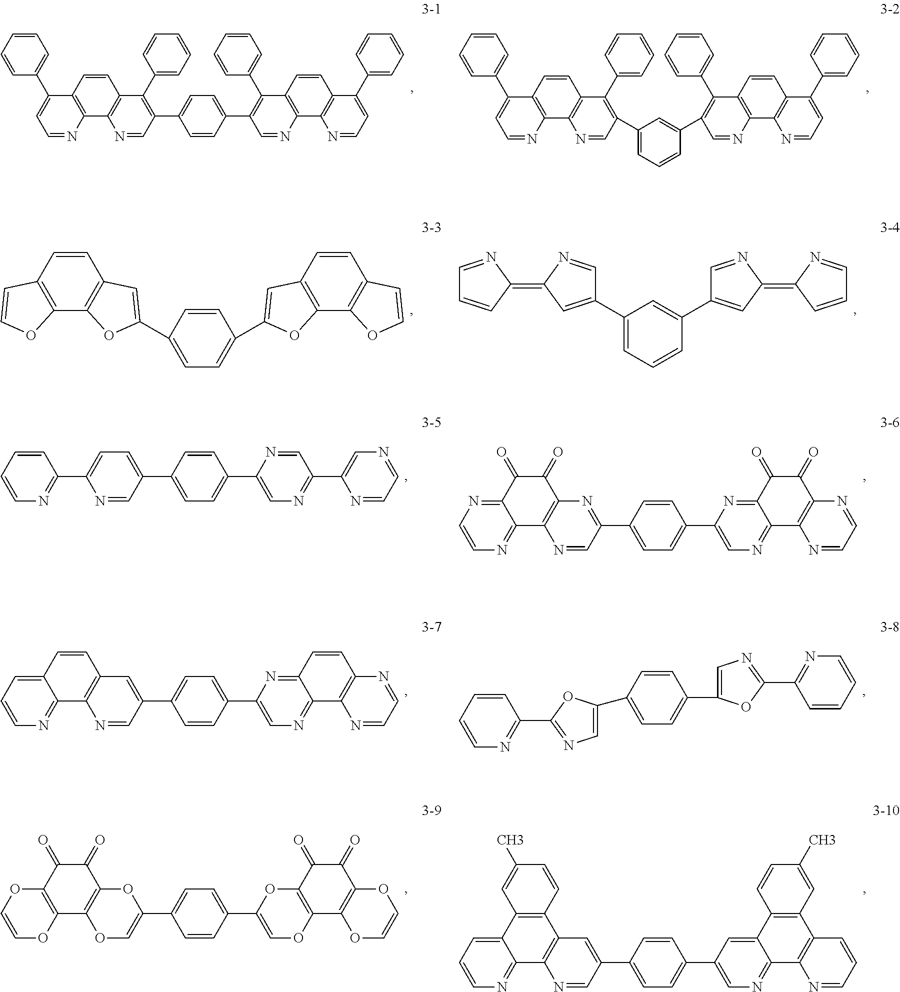

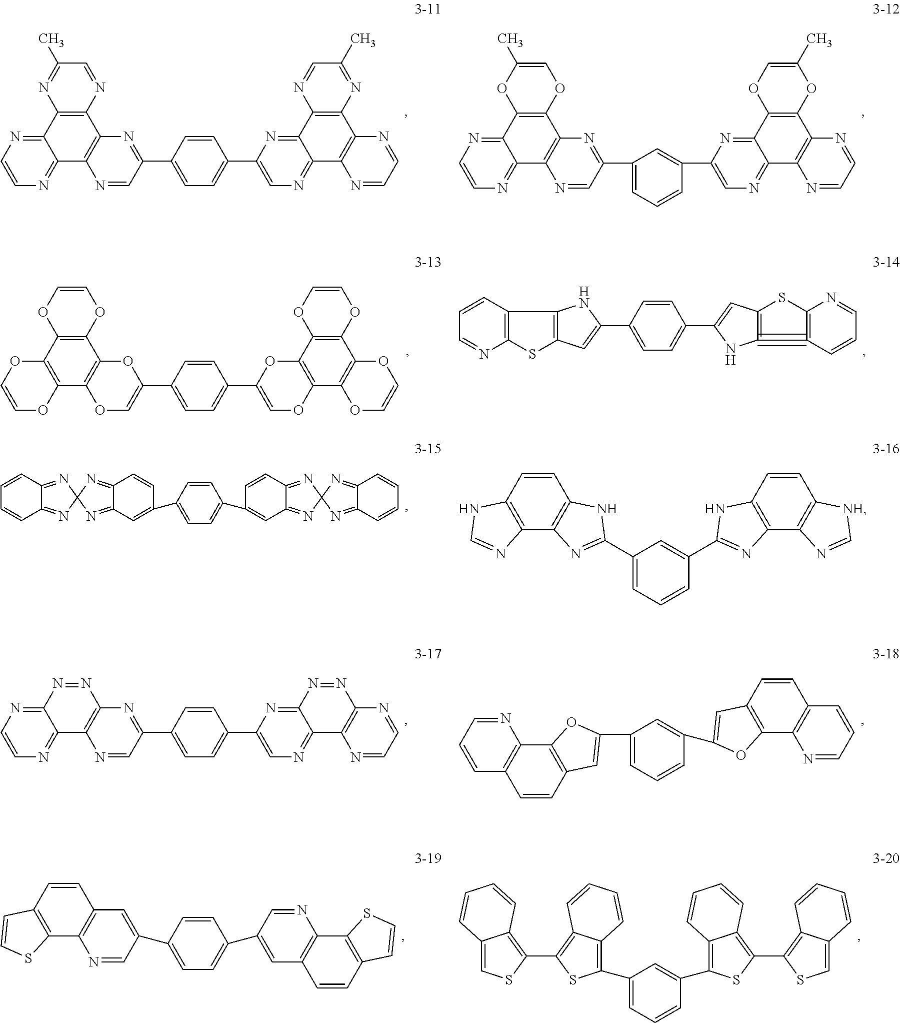

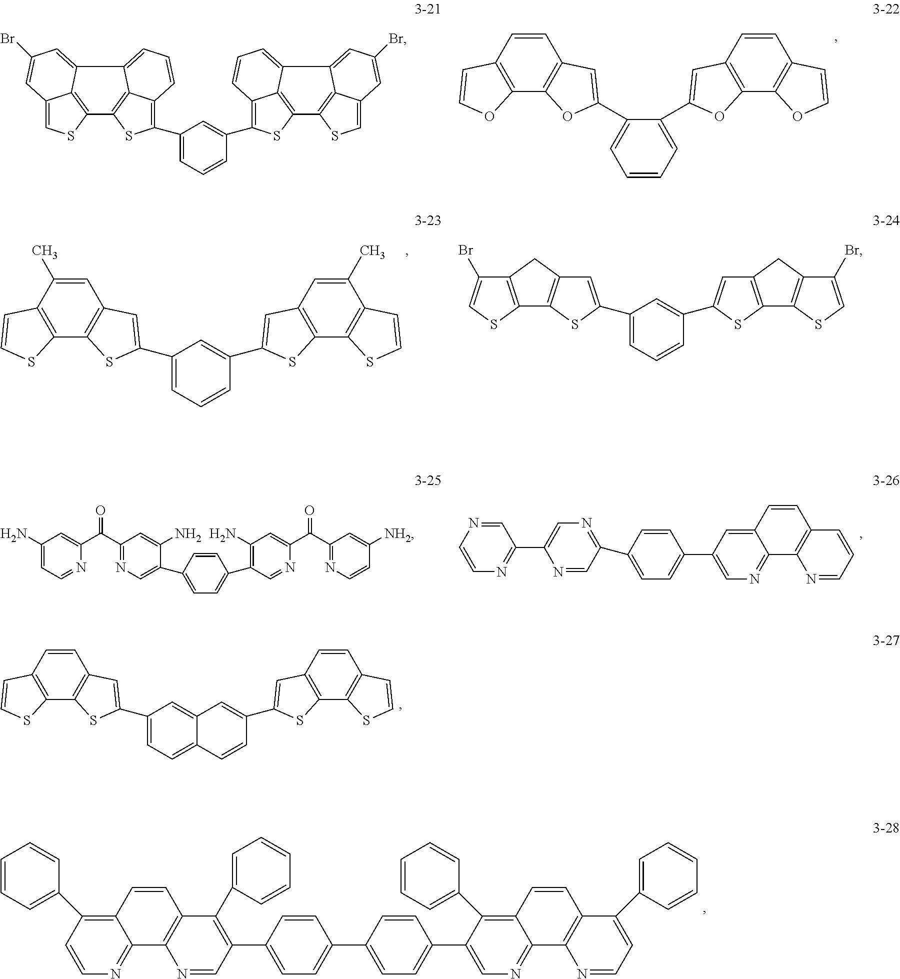

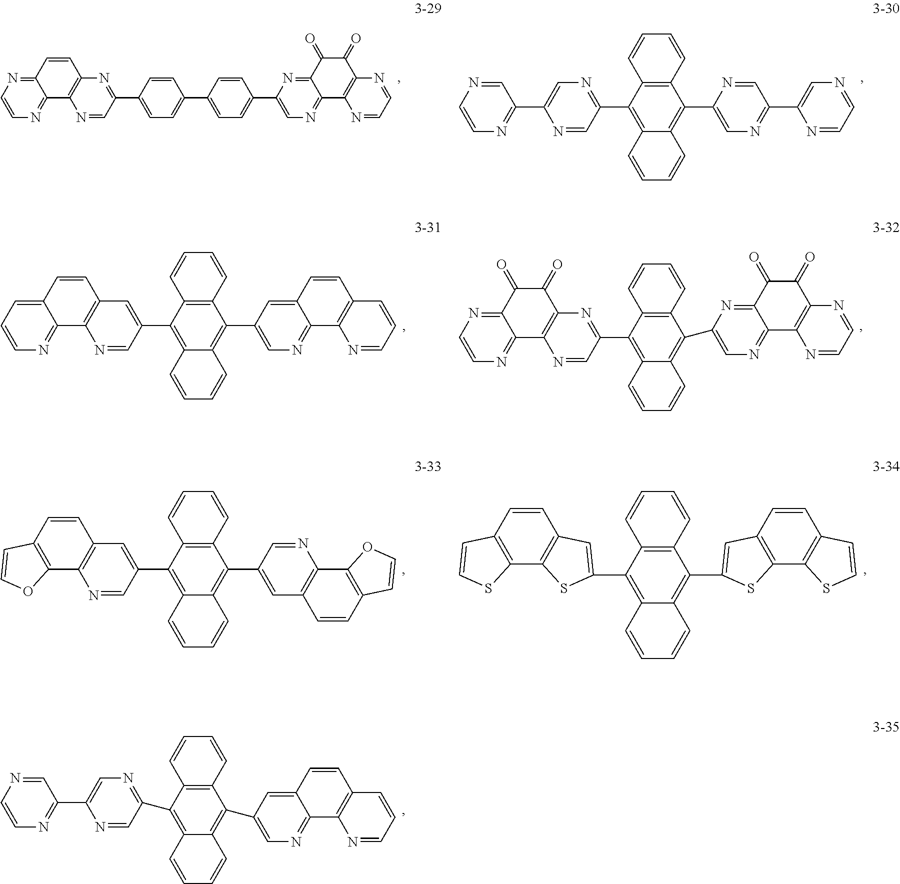

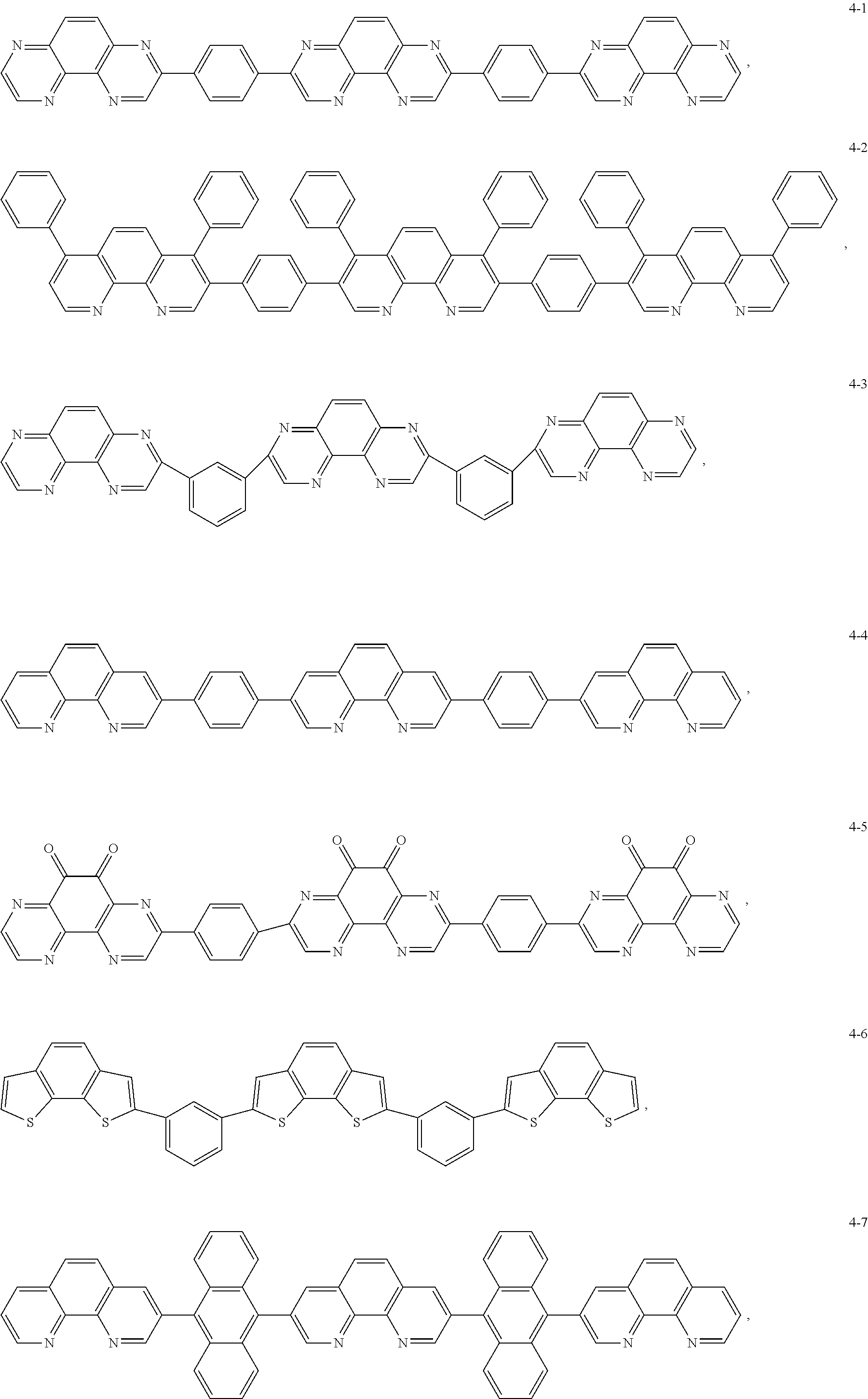

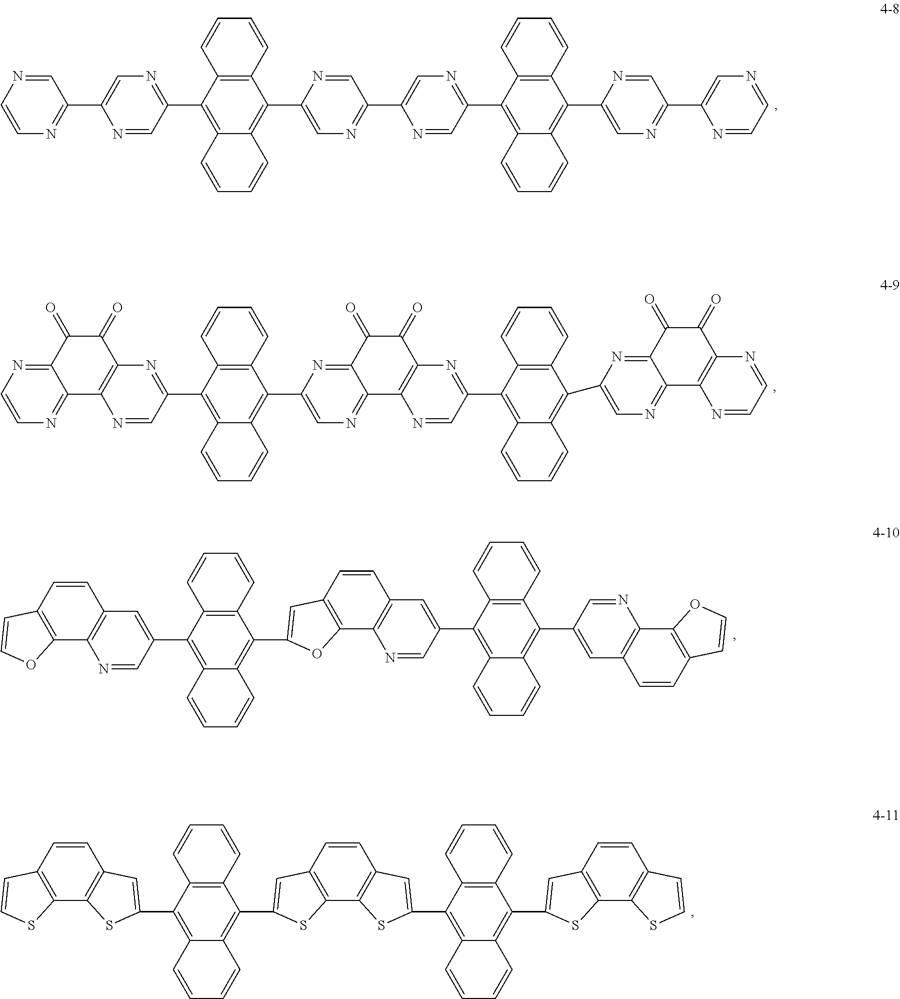 [SMILES: c1ccc2c(-c3cnc(-c4cnc(-c5c6ccccc6c(-c6cnc(-c7cnccn7)cn6)c6ccccc56)cn4)cn3)c3ccccc3c(-c3cnc(-c4cnccn4)cn3)c2c1 ; O=C1C(=O)c2nc(-c3c4ccccc4c(-c4cnc5c(n4)C(=O)C(=O)c4nc(-c6c7ccccc7c(-c7cnc8c(n7)C(=O)C(=O)c7nccnc7-8)c7ccccc67)cnc4-5)c4ccccc34)cnc2-c2nccnc21 ; c1ccc2c(-c3cnc4c(ccc5cc(-c6c7ccccc7c(-c7cnc8c(ccc9ccoc98)c7)c7ccccc67)oc54)c3)c3ccccc3c(-c3cnc4c(ccc5ccoc54)c3)c2c1 ; c1ccc2c(-c3cc4ccc5cc(-c6c7ccccc7c(-c7cc8ccc9ccsc9c8s7)c7ccccc67)sc5c4s3)c3ccccc3c(-c3cc4ccc5ccsc5c4s3)c2c1]

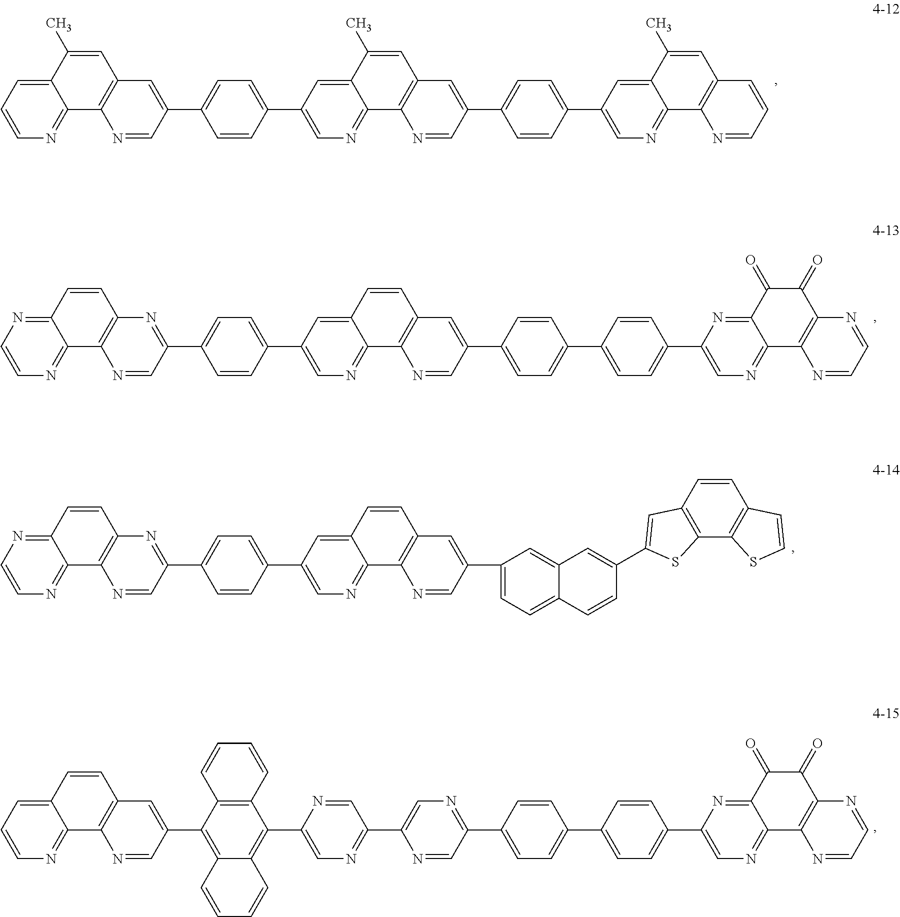 [SMILES: Cc1cc2cc(-c3ccc(-c4cnc5c(c4)c(C)cc4cc(-c6ccc(-c7cnc8c(c7)c(C)cc7cccnc78)cc6)cnc45)cc3)cnc2c2ncccc12 ; O=C1C(=O)c2nc(-c3ccc(-c4ccc(-c5cnc6c(ccc7cc(-c8ccc(-c9cnc%10c(ccc%11nccnc%11%10)n9)cc8)cnc76)c5)cc4)cc3)cnc2-c2nccnc21 ; c1cnc2c(ccc3nc(-c4ccc(-c5cnc6c(ccc7cc(-c8ccc9ccc(-c%10cc%11ccc%12ccsc%12c%11s%10)cc9c8)cnc76)c5)cc4)cnc32)n1 ; O=C1C(=O)c2nc(-c3ccc(-c4ccc(-c5cnc(-c6cnc(-c7c8ccccc8c(-c8cnc9c(ccc%10cccnc%109)c8)c8ccccc78)cn6)cn5)cc4)cc3)cnc2-c2nccnc21]

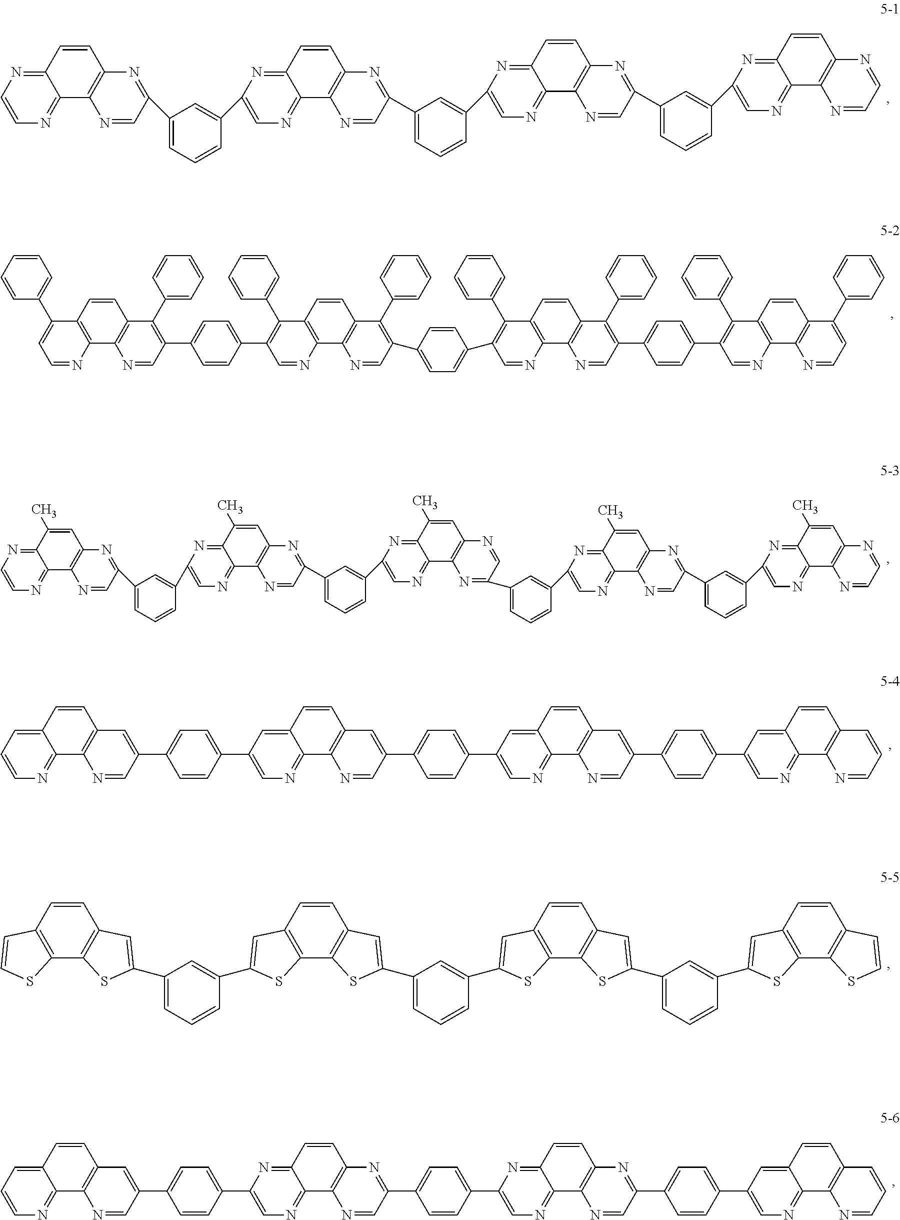

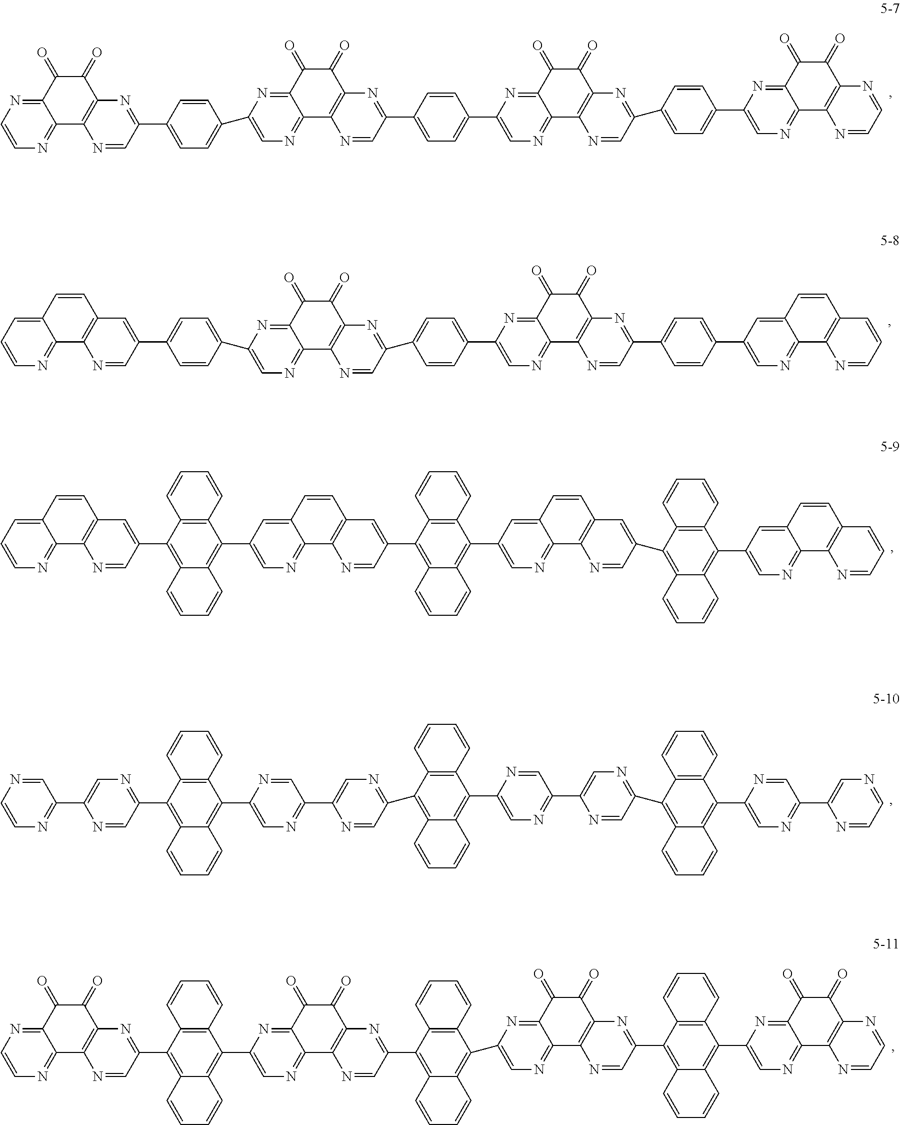

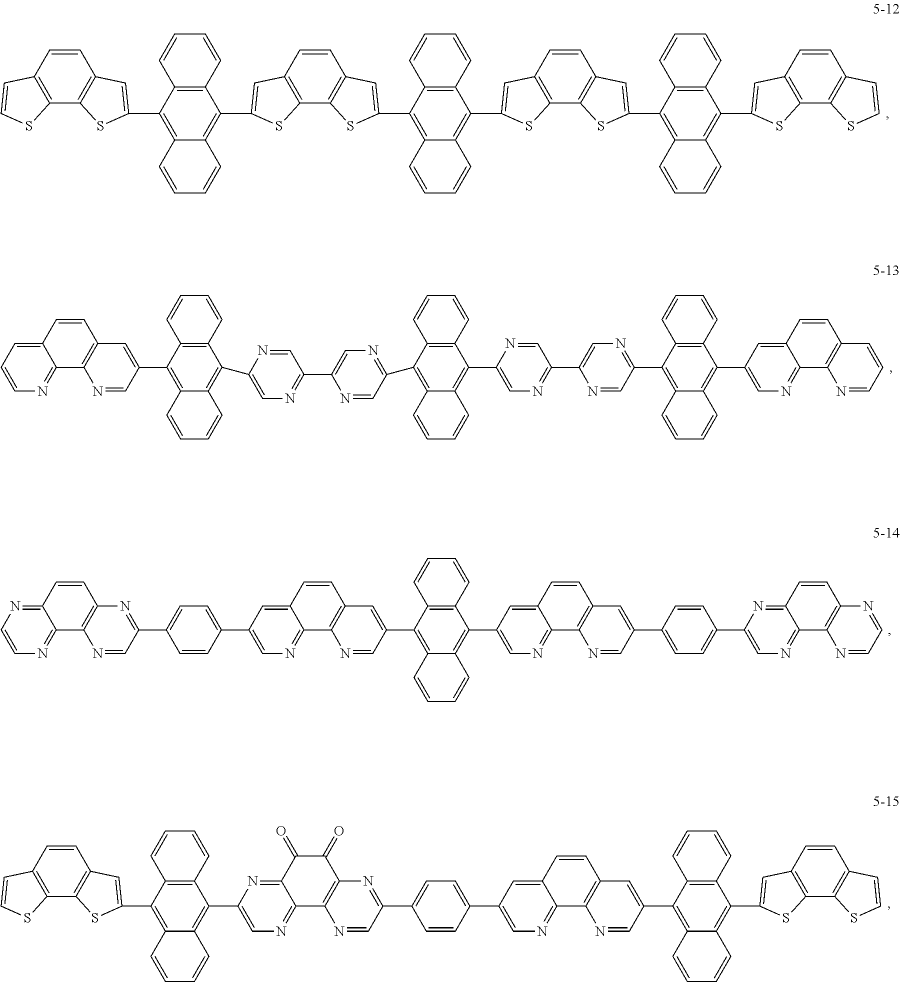

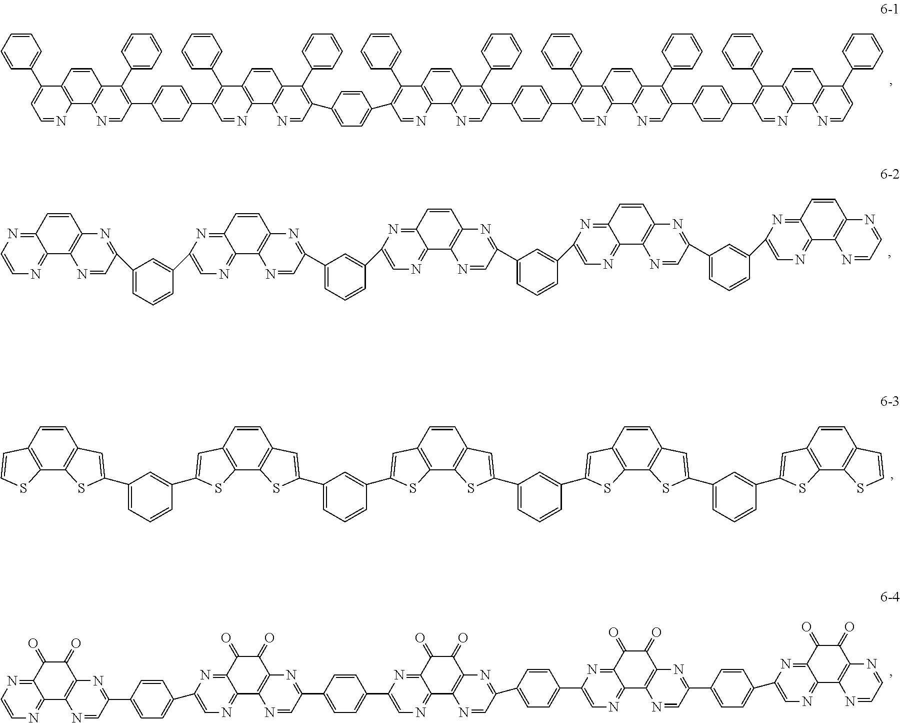

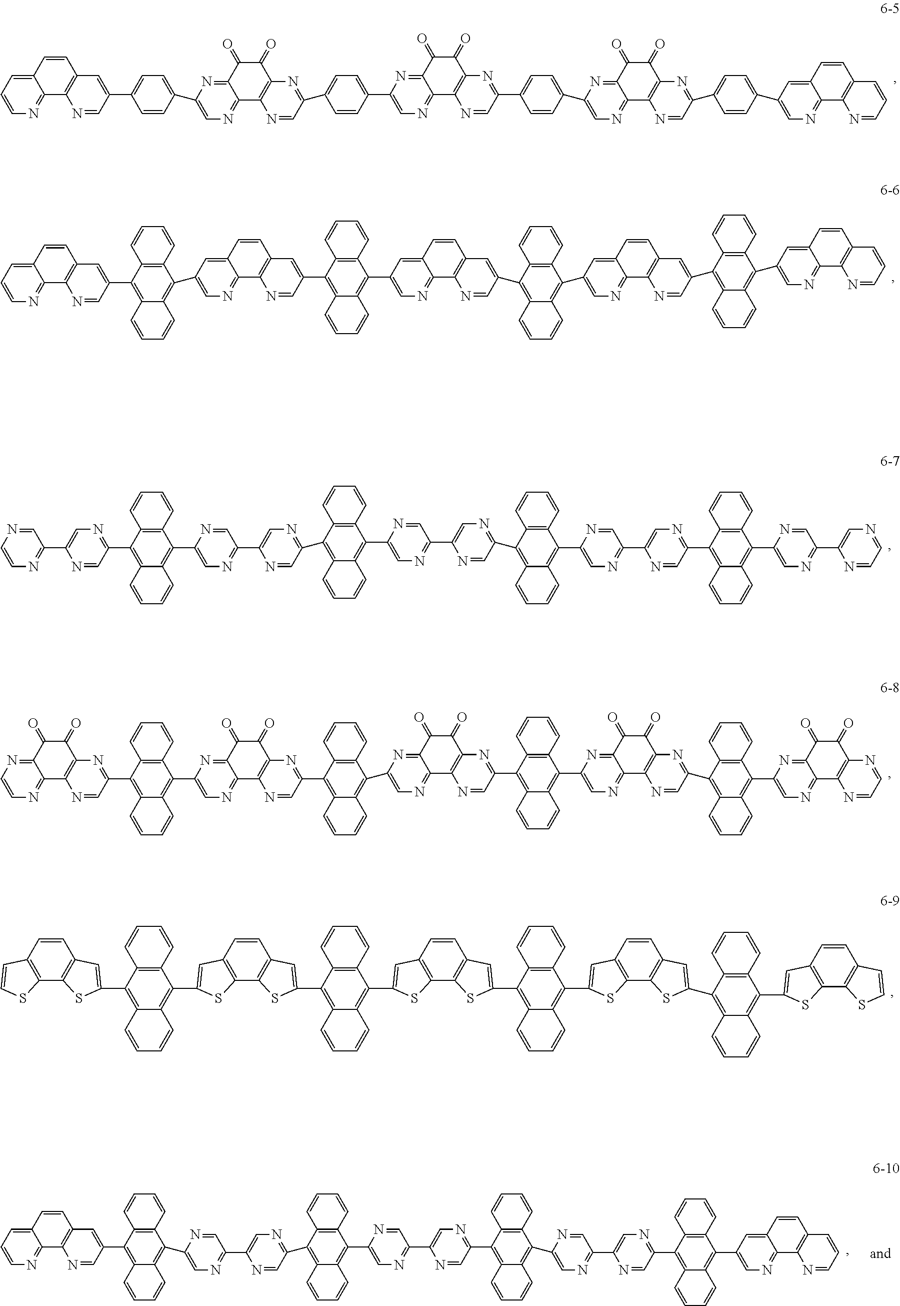

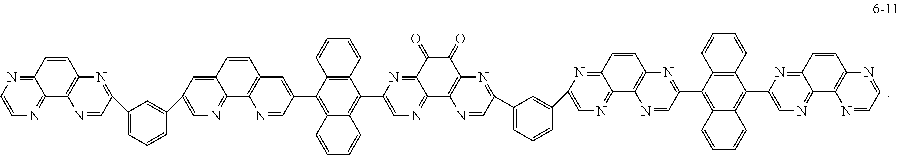 [SMILES: O=C1C(=O)c2nc(-c3c4ccccc4c(-c4cnc5c(ccc6cc(-c7cccc(-c8cnc9c(ccc%10nccnc%109)n8)c7)cnc65)c4)c4ccccc34)cnc2-c2ncc(-c3cccc(-c4cnc5c(ccc6nc(-c7c8ccccc8c(-c8cnc9c(ccc%10nccnc%109)n8)c8ccccc78)cnc65)n4)c3)nc21]

The inert metal is at least one selected from the group consisting of titanium, vanadium, chromium, manganese, iron, cobalt, nickel, copper (Cu), zinc, zirconium, niobium, molybdenum, technetium, ruthenium, rhodium, lead, silver (Ag), cadmium, tantalum, tungsten, rhenium, osmium, iridium, gold (Au), platinum, and mercury. In addition, the inert metal is at least one selected from the group consisting of cobalt, nickel, copper, ruthenium, silver, iridium, gold, and platinum. Moreover, the inert metal is silver.

A mass ratio of the inert metal to the organic compound in the electron transporting layer ranges from 5:100 to 50:100. When the mass ratio of the inert metal to the long-chain organic compound is less than 5:100, a content of the inert metal in the electron transporting layer is too low to reduce the electron mobility. When the mass ratio of the inert metal to the long-chain organic compound is greater than 50:100, other performance properties such as flexibility and light transmittance of the device are affected.

The aforementioned electron transporting layer has at least the following advantages:

(1) The organic compound in the aforementioned electron transporting layer contains at least one heterocyclic coordination structure selected from the group consisting of a nitrogen-oxygen coordination group, a nitrogen-sulfur coordination group, a sulfur-oxygen coordination group, a sulfur-sulfur coordination group, an oxygen-oxygen coordination group, and a nitrogen-nitrogen coordination group. When such coordination structure is coordinated with the inert metal, the van der Waals force between the molecules of the previous organic compounds becomes a coordination force. It increases the interaction force between the molecules of the organic compounds, reduces the distance between the molecules of the organic compounds, reduces the transporting barrier of the carrier, and significantly improves the mobility of the electron transporting layer.

(2) Since the aforementioned organic compound contains one or more heterocyclic coordination structures, the distance between the molecules can be further reduced after coordination with the inert metal, and the long-chain structure of the ligand is favorable for constructing a channel for carrier transporting, thereby further improving the mobility.

(3) The inert metal can achieve a good n-type doping effect in the ligand structure, which can greatly increase the carrier concentration, and the conductivity of the electron transporting layer can be enhanced while the exogenous carrier is filled with the trap state of the original electron transporting layer.

(4) The thermal stability of this organic-inorganic material composite film (electron transporting layer material) is remarkably improved. It is favorable for the improvement of the thermal stability of the electron transporting layer. The transporting layer is not easily crystallized during evaporation at a higher temperature, and the stable transporting effect of the transporting layer can be maintained.

A method of preparing an electron transporting layer according to an embodiment is to co-evaporate the aforementioned inert metal and the aforementioned organic compound.

An organic electronic device according to an embodiment includes the aforementioned electron transporting layer. The organic electronic device is selected from the group consisting of a TOF (Time of flight) device, a single carrier device, and an organic electroluminescence device.

The electron transporting layer has a thickness of 1 nm to 200 nm. When the thickness of the electron transporting layer is less than 1 nm or greater than 200 nm, the recombination of carriers in the luminescence layer is disadvantageous. In addition, the electron transporting layer has a thickness of 5 nm to 50 nm.

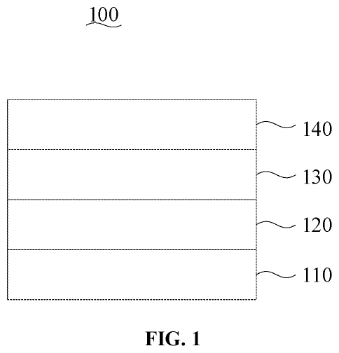

Referring to FIG. 1, a TOF (Time of flight) device 100 according to an embodiment includes a substrate 110, a first electrode 120, an electron transporting layer 130, and a second electrode 140. The first electrode 120 is an ITO (Indium tin oxide) layer, a raw material of the electron transporting layer 130 includes the aforementioned inert metal and the aforementioned organic compound, and the second electrode 140 is Ag.

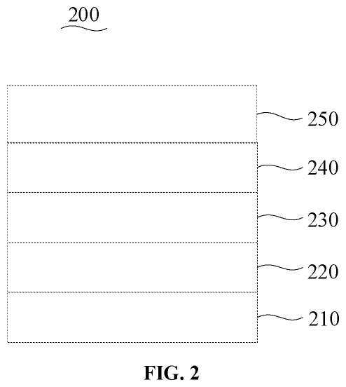

Referring to FIG. 2, a single carrier device 200 includes a substrate 210, a first electrode 220, a blocking layer 230, an electron transporting layer 240, and a second electrode 250. The first electrode 220 is an ITO layer. The blocking layer 230 is a BCP (2, 9-dimethyl-4, 7-diphenyl-1, 10-o-phenanthroline) layer. A raw material of the electron transporting layer 240 includes the aforementioned inert metal and the aforementioned organic compound. The second electrode 250 is an Al layer.

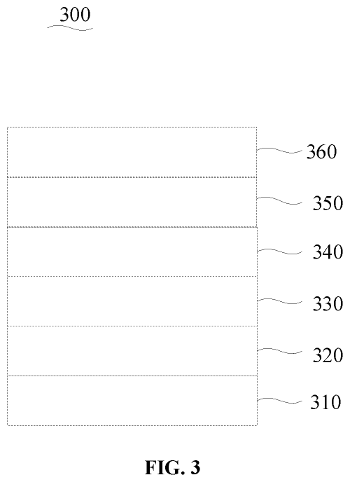

Referring to FIG. 3, an organic electroluminescence device 300 according to an embodiment includes a substrate 310, a first electrode 320, a hole transporting layer 330, a luminescence layer 340, an electron transporting layer 350, and a second electrode 360. The first electrode 320 is an ITO layer. The hole transporting layer 330 is an NPB (N, N′-bis(1-naphthyl)-N, N′-diphenyl-1, 1′-biphenyl-4, 4′-diamine) layer. The luminescence layer 340 is an Alq3 (8-hydroxyquinoline aluminum) layer. A raw material of the electron transporting layer 350 includes the aforementioned inert metal and the aforementioned organic compound. The second electrode 360 is an aluminum (Al) layer.

The aforementioned organic electroluminescence device uses the aforementioned electron transporting layer, and since the aforementioned electron transporting layer has effects of enhancing the conductivity of the electron transporting layer and increasing the mobility of the electron transporting layer, the organic electroluminescence device has effects of lowering the voltage, reducing the efficiency roll-off, and increasing the luminescence lifetime of the device.

A display according to an embodiment includes the aforementioned organic electroluminescence device. The aforementioned display uses the aforementioned electron transporting layer, and since the aforementioned electron transporting layer has effects of enhancing the conductivity of the electron transporting layer and increasing the mobility of the electron transporting layer, the display using the organic electroluminescence device has effects of lowering the voltage, reducing the efficiency roll-off, and increasing the luminescence lifetime of the device.

### Example 1

A time of flight (TOF) device according to the present embodiment had a structure of: substrate/ITO (150 nm)/Ag (5%): Bphen-2 (95%) (1 μm)/Ag (150 nm). ITO was a first electrode and had a thickness of 150 nm. Ag (5%): Bphen-2 (95%) (1 μm) was an electron transporting layer, and the electron transporting layer was formed by evaporation of a raw material of the electron transporting layer. The raw material of the electron transporting layer included Ag and Bphen-2 having a mass ratio of 5:95. The electron transporting layer had a thickness of 1 μm. Ag was a second electrode. “/” means lamination, which is the same below.

Bphen-2 had the following formula:

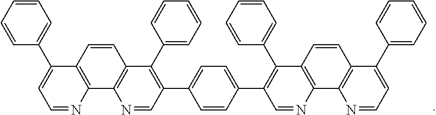 [SMILES: c1ccc(-c2ccnc3c2ccc2c(-c4ccccc4)c(-c4ccc(-c5cnc6c(ccc7c(-c8ccccc8)ccnc76)c5-c5ccccc5)cc4)cnc23)cc1]

### Example 2

The structure of the TOF device according to the present embodiment was substantially the same as that of Example 1. The difference was that a mass ratio of Ag and Bphen-2 in the raw material of the electron transporting layer was 20:80.

### Example 3

The structure of the TOF device according to the present embodiment was substantially the same as that of Example 1. The difference was that a mass ratio of Ag and Bphen-2 in the raw material of the electron transporting layer was 30:70.

### Example 4

The structure of the TOF device according to the present embodiment was substantially the same as that of Example 1. The difference was that the inert metal in the raw material of the electron transporting layer was Cu.

### Example 5

The structure of the TOF device according to the present embodiment was substantially the same as that of Example 1. The difference was that the inert metal in the raw material of the electron transporting layer was Au.

### Example 6

The structure of the TOF device according to the present embodiment was substantially the same as that of Example 3. The difference was that the organic compound in the raw material of the electron transporting layer was a compound represented by the above formula 4-2, and the specific formula was as follows:

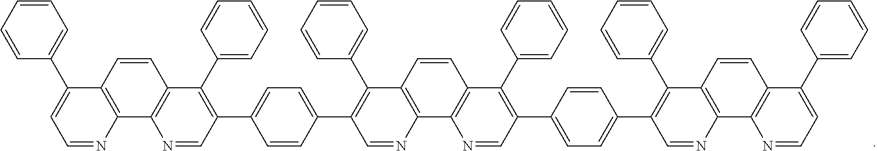 [SMILES: c1ccc(-c2ccnc3c2ccc2c(-c4ccccc4)c(-c4ccc(-c5cnc6c(ccc7c(-c8ccccc8)c(-c8ccc(-c9cnc%10c(ccc%11c(-c%12ccccc%12)ccnc%11%10)c9-c9ccccc9)cc8)cnc76)c5-c5ccccc5)cc4)cnc23)cc1]

### Example 7

The structure of the TOF device according to the present embodiment was substantially the same as that of Example 3. The difference was that the organic compound in the raw material of the electron transporting layer was a compound represented by the above formula 4-7, and the specific formula was as follows:

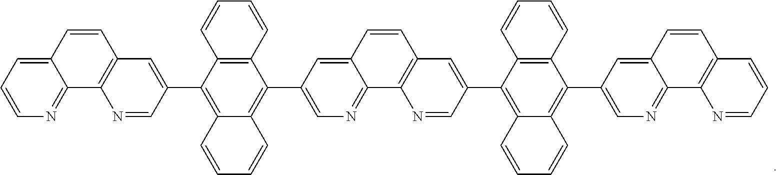 [SMILES: c1cnc2c(c1)ccc1cc(-c3c4ccccc4c(-c4cnc5c(ccc6cc(-c7c8ccccc8c(-c8cnc9c(ccc%10cccnc%109)c8)c8ccccc78)cnc65)c4)c4ccccc34)cnc12]

### Example 8

The structure of the TOF device according to the present embodiment was substantially the same as that of Example 3. The difference was that the organic compound in the raw material of the electron transporting layer was a compound represented b the above formula 5-2, and the specific formula was as follows:

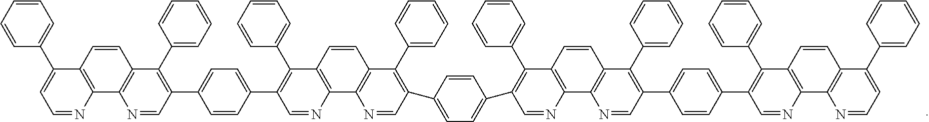 [SMILES: c1ccc(-c2ccnc3c2ccc2c(-c4ccccc4)c(-c4ccc(-c5cnc6c(ccc7c(-c8ccccc8)c(-c8ccc(-c9cnc%10c(ccc%11c(-c%12ccccc%12)c(-c%12ccc(-c%13cnc%14c(ccc%15c(-c%16ccccc%16)ccnc%15%14)c%13-c%13ccccc%13)cc%12)cnc%11%10)c9-c9ccccc9)cc8)cnc76)c5-c5ccccc5)cc4)cnc23)cc1]

### Example 9

The structure of the TOF device according to the present embodiment was substantially the same as that of Example 3. The difference was that the organic compound in the raw material of the electron transporting layer was a compound represented by the above formula 5-6, and the specific formula was as follows:

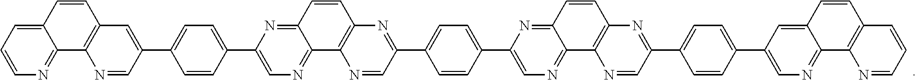 [SMILES: c1cnc2c(c1)ccc1cc(-c3ccc(-c4cnc5c(ccc6nc(-c7ccc(-c8cnc9c(ccc%10nc(-c%11ccc(-c%12cnc%13c(ccc%14cccnc%14%13)c%12)cc%11)cnc%109)n8)cc7)cnc65)n4)cc3)cnc12]

### Example 10

The structure of the TOF device according to the present embodiment was substantially the same as that of Example 3. The difference was that the organic compound in the raw material of the electron transporting layer was a compound represented by the above formula 6-1, and the specific formula was as follows:

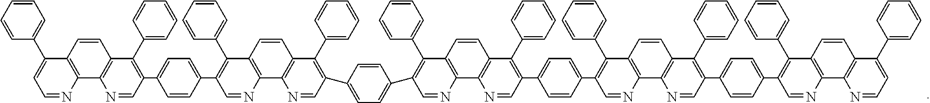 [SMILES: c1ccc(-c2ccnc3c2ccc2c(-c4ccccc4)c(-c4ccc(-c5cnc6c(ccc7c(-c8ccccc8)c(-c8ccc(-c9cnc%10c(ccc%11c(-c%12ccccc%12)c(-c%12ccc(-c%13cnc%14c(ccc%15c(-c%16ccccc%16)c(-c%16ccc(-c%17cnc%18c(ccc%19c(-c%20ccccc%20)ccnc%19%18)c%17-c%17ccccc%17)cc%16)cnc%15%14)c%13-c%13ccccc%13)cc%12)cnc%11%10)c9-c9ccccc9)cc8)cnc76)c5-c5ccccc5)cc4)cnc23)cc1]

### Example 11

The structure of the TOF device according to the present embodiment was substantially the same as that of Example 3. The difference was that the organic compound in the raw material of the electron transporting layer was a compound represented by the above formula 6-6, and the specific formula was as follows:

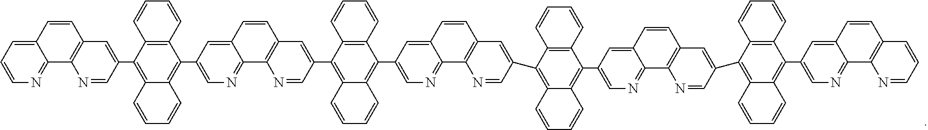 [SMILES: c1cnc2c(c1)ccc1cc(-c3c4ccccc4c(-c4cnc5c(ccc6cc(-c7c8ccccc8c(-c8cnc9c(ccc%10cc(-c%11c%12ccccc%12c(-c%12cnc%13c(ccc%14cc(-c%15c%16ccccc%16c(-c%16cnc%17c(ccc%18cccnc%18%17)c%16)c%16ccccc%15%16)cnc%14%13)c%12)c%12ccccc%11%12)cnc%109)c8)c8ccccc78)cnc65)c4)c4ccccc34)cnc12]

### Comparative Example 1

The structure of the TOF device according to the present comparative example was substantially the same as that of Example 1. The difference was that the raw material of the electron transporting layer was Bphen-2.

### Comparative Example 2

The structure of the TOF device according to the present comparative example was substantially the same as that of Example 1. The difference was that the raw material of the electron transporting layer was Bphen (4, 7-diphenyl-1, 10-phenanthroline), and the structure was as follows:

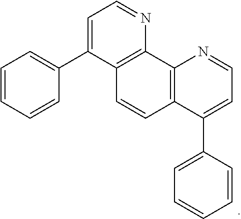 [SMILES: c1ccc(-c2ccnc3c2ccc2c(-c4ccccc4)ccnc23)cc1]

### Comparative Example 3

The structure of the TOF device according to the present comparative example was substantially the same as that of Example 1. The difference was that the raw material of the electron transporting layer included Ag and Bphen having a mass ratio of 30:70.

Electron mobility tests were carried out on Examples 1 to 11 and Comparative Examples 1 to 3 using the Time of Flight method. The test results were shown in Table 1:

TABLE 1
Results of Electron Mobility Tests

| | | Electron |
|---|---|---|
| | | Mobility |
| | Electron Transporting Material | (cm² V⁻¹ s⁻¹) |
| Example 1 | Ag and Bphen-2 in a mass ratio of 5:95 | 8.7 * 10⁻³ |
| Example 2 | Ag and Bphen-2 in a mass ratio of 20:80 | 9.6 * 10⁻³ |
| Example 3 | Ag and Bphen-2 in a mass ratio of 30:70 | 1.1 * 10⁻² |
| Example 4 | Cu and Bphen-2 in a mass ratio of 5:95 | 7.9 * 10⁻³ |
| Example 5 | Au and Bphen-2 in a mass ratio of 5:95 | 9.2 * 10⁻³ |
| Example 6 | Ag and the organic compound | 1.5 * 10⁻² |
| | represented by the formula 4-2 in a mass | |
| | ratio of 30:70 | |
| Example 7 | Ag and the organic compound | 1.4 * 10⁻² |
| | represented by the formula 4-7 in a mass | |
| | ratio of 30:70 | |
| Example 8 | Ag and the organic compound | 1.9 * 10⁻² |
| | represented by the formula 5-2 in a mass | |
| | ratio of 30:70 | |
| Example 9 | Ag and the organic compound | 1.8 * 10⁻² |
| | represented by the formula 5-6 in a mass | |
| | ratio of 30:70 | |
| Example 10 | Ag and the organic compound | 2.3 * 10⁻² |
| | represented by the formula 6-1 in a mass | |
| | ratio of 30:70 | |
| Example 11 | Ag and the organic compound | 2.1 * 10⁻² |
| | represented by the formula 6-6 in a mass | |
| | ratio of 30:70 | |
| Comparative | Bphen-2 | 6.2 * 10⁻⁴ |
| Example 1 | | |
| Comparative | Bphen | 2.1 * 10⁻⁴ |
| Example 2 | | |
| Comparative | Ag and Bphen in a mass ratio of 30:70 | 8.2 * 10⁻³ |
| Example 3 | | |

As can be seen from the results of the electron mobilities in Table 1, the inert metals such as Ag, Cu, and Au are doped in the organic compound to coordinate and form the electron transporting layer, and the electron mobility of the TOF device prepared by using the electron transporting layer is significantly improved. In addition, the mobility of the electron transporting layer gradually increases as the content of the inert metal in the electron transporting layer increases. It indicates that the inclusion of the inert metal in the electron transporting layer facilitates the improvement of the carrier mobility of the electron transporting layer.

As can be seen from the results of the electron mobilities of Examples 3, 6-11 and Comparative Example 3, the electron mobility of the electron transporting layer gradually increases as the length of the molecular chain of the organic compound increases. It indicates that as the length of the molecular chain of the organic compound increases, the heterocyclic coordination structure thereof also increases, so that the distance between the molecules is further reduced after the organic compound is coordinated with the inert metal, and the long-chain structure of the organic compound is favorable for constructing a channel for carrier transporting, thereby further improving the electron mobility.

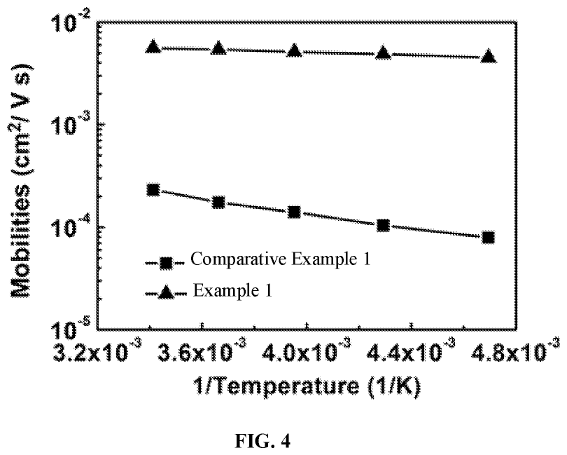

Carrier mobilities of Examples 1 and Comparative Example 1 were tested at different temperatures using a TOF (Time of Flight) test, and the results were shown in FIG. 4.

As can be seen from FIG. 4, at the same temperature, the carrier mobility of the TOF device of Example 1 is higher than that of the TOF device of Comparative Example 1, indicating that the presence of inert metal Ag in the electron transporting layer results in a decrease in the electron transporting barrier and facilitates the improvement of the electron mobility.

### Example 12

A single carrier device according to the present embodiment had a structure of: ITO (150 nm)/BCP (10 nm)/Ag (5%): Bphen-2 (95%) (100 nm)/Al (150 nm). ITO was a first electrode and had a thickness of 150 nm. BCP (2, 9-dimethyl-4, 7-diphenyl-1, 10-o-phenanthroline) was a blocking layer with a thickness of 10 nm. Ag (5%): Bphen-2 (95%) was an electron transporting layer, and the electron transporting layer was formed by evaporation of a raw material of the electron transporting layer. The raw material of the electron transporting layer included Ag and Bphen-2 (1, 4-bis-(4, 7-diphenyl-1, 10-phenanthrolinyl-3-)benzene) having a mass ratio of 5:95. The electron transporting layer had a thickness of 100 nm. Al was a second electrode and had a thickness of 150 nm.

### Example 13

The structure of the single carrier device according to the present embodiment was substantially the same as that of Example 12. The difference was that a mass ratio of Ag and Bphen-2 in the raw material of the electron transporting layer was 20:80.

### Example 14

The structure of the single carrier device according to the present embodiment was substantially the same as that of Example 12. The difference was that a mass ratio of Ag and Bphen-2 in the raw material of the electron transporting layer was 30:70.

### Example 15

The structure of the single carrier device according to the present embodiment was substantially the same as that of Example 12. The difference was that the organic compound in the raw material of the electron transporting layer was Bphen (4, 7-diphenyl-1, 10-phenanthroline), and a mass ratio of Ag to Bphen was 30:70.

### Comparative Example 4

The structure of the single carrier device according to the present comparative example was substantially the same as that of Example 12. The difference was that the electron transporting layer was a Bphen-2 layer.

### Comparative Example 5

The structure of the single carrier device according to the present comparative example was substantially the same as that of Example 12. The difference was that the raw material of the electron transporting layer was Bphen-2, and the electron transporting layer further includes an electron injection layer having a thickness of 1 nm. The electron injection material is LiF.

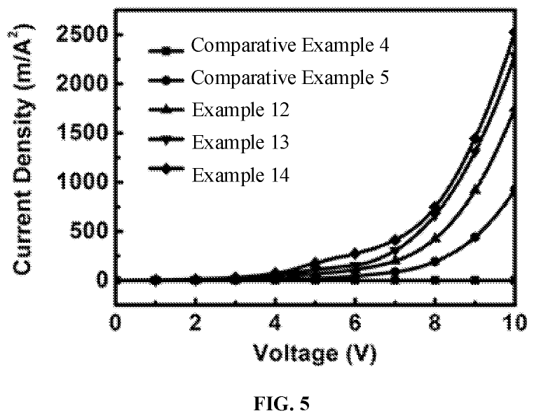

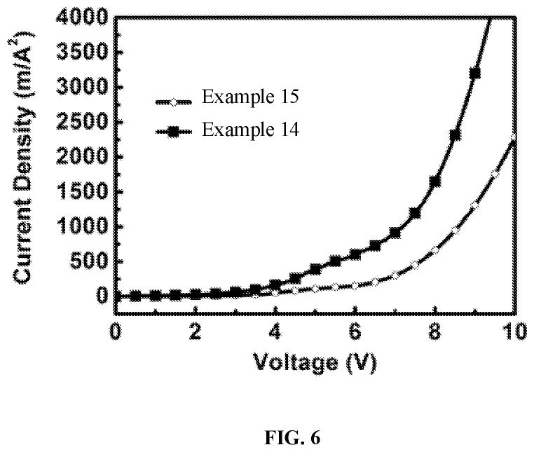

Current density-voltage tests were performed on the single carrier devices of Examples 12 to 15 and Comparative Examples 4 to 5 using a Keithley K 2400 digital source meter system, and the results were shown in FIGS. 5 and 6.

As can be seen from FIG. 5, the single carrier devices of Examples 12 to 14 have higher current densities at the same voltage than the single carrier devices of Comparative Examples 4 to 5. It indicates that the electron transporting performances of the single carrier devices of Examples 12 to 14 are better, and the electron mobility of the electron transporting layer can be improved by doping inert metal Ag in the electron transporting layer. In addition, the single carrier device in Comparative Example 5 includes an electron transporting layer and an electron injection layer, while the electron transporting performances of the single carrier devices of Examples 12 to 14 are still superior to that of the single carrier device in Comparative Example 5, indicating that the presence of the inert metal Ag in the electron transporting layer not only facilitates the electron transporting, but also improves the electron injection, which is even more effective than that of the electron injection layer using LiF material.

Moreover, as can be seen from the current density-voltage curves of Examples 12 to 14 in FIG. 5, as the content of Ag in the electron transporting layer increases, the electron transporting performance is gradually improved, and is optimal when the content of Ag reaches 30% by mass.

As can be seen from FIG. 6, on the premise that the content of the inert metal Ag in the electron transporting layer is the same, the single carrier device of Example 14 has a higher current density at the same voltage than that of the single carrier device of Example 15. It indicates that the coordination of the inert metal with the long-chain organic compound as a ligand in the electron transporting layer facilitates the increase of carrier mobility.

### Example 16

An organic electroluminescence device according to the present embodiment had a structure of: ITO (150 nm)/NPB (40 nm)/Alq3 (30 nm)/Ag (5%): Bphen-2 (95%) (30 nm)/Al (150 nm). ITO was a first electrode and had a thickness of 150 nm. NPB (N, N′-bis(1-naphthyl)-N, N′-diphenyl-1, 1′-biphenyl-4, 4′-diamine) was a hole transporting layer with a thickness of 40 nm. Alq3 (8-hydroxyquinoline aluminum) was a luminescence layer with a thickness of 30 nm. Ag (5%): Bphen-2 (95%) was an electron transporting layer, and the electron transporting layer was formed by evaporation of a raw material of the electron transporting layer. The raw material of the electron transporting layer included Ag and Bphen-2 (1, 4-bis-(4, 7-diphenyl-1, 10-phenanthrolinyl-3-)benzene) having a mass ratio of 5:95. Al was a second electrode and had a thickness of 150 nm.

### Example 17

The structure of the organic electroluminescence device according to the present embodiment was substantially the same as that of Example 16. The difference was that a mass ratio of Ag and Bphen-2 in the raw material of the electron transporting layer was 20:80.

### Example 18

The structure of the organic electroluminescence device according to the present embodiment was substantially the same as that of Example 16. The difference was that a mass ratio of Ag and Bphen-2 in the raw material of the electron transporting layer was 30:70.

### Comparative Example 6

The structure of the organic electroluminescence device according to the present embodiment was substantially the same as that of Example 16. The difference was that the raw material of the electron transporting layer was Bphen-2, and the electron transporting layer further includes an electron injection layer having a film thickness of 1 nm. The electron injection material is LiF.

### Example 19

The structure of the organic electroluminescence device according to the present embodiment was substantially the same as that of Example 16. The difference was that the raw material of the electron transporting layer includes cobalt and an organic compound having a structure represented by Formula 3-7, and a mass ratio of cobalt to the organic compound having the structure represented by Formula 3-7 ranges from 20:80.

### Example 20

The structure of the organic electroluminescence device according to the present embodiment was substantially the same as that of Example 16. The difference was that the raw material of the electron transporting layer includes copper and an organic compound having a structure represented by Formula 3-27, and a mass ratio of copper to the organic compound having the structure represented by Formula 3-27 ranges from 10:90.

### Example 21

The structure of the organic electroluminescence device according to the present embodiment was substantially the same as that of Example 16. The difference was that the raw material of the electron transporting layer includes gold and an organic compound having a structure represented by Formula 3-31, and a mass ratio of gold to the organic compound having the structure represented by Formula 3-31 ranges from 20:80.

### Example 22

The structure of the organic electroluminescence device according to the present embodiment was substantially the same as that of Example 16. The difference was that the raw material of the electron transporting layer includes platinum and an organic compound having a structure represented by Formula 4-4, and a mass ratio of platinum to the organic compound having the structure represented by Formula 4-4 ranges from 15:85.

The organic electroluminescence devices of Examples 16 to 22 and Comparative Example 6 were tested for current, voltage, luminance, and luminescence spectrum simultaneously by using a PR 650 spectral scanning luminance meter and a Keithley K 2400 digital source meter system, and the results were shown in Table 2:

TABLE 2
Performance Test Results of Organic Electroluminescence Devices

| | Voltage (V) at a luminance | Current efficiency (cd/A) at |
|---|---|---|
| | of 1000 cd/m² | a luminance of 1000 cd/m² |
| Example 16 | 6.2 | 2.3 |
| Example 17 | 5.2 | 2.5 |
| Example 18 | 4.7 | 3.1 |
| Comparative | 8.1 | 1.7 |
| Example 6 | | |
| Example 19 | 6.7 | 2.2 |
| Example 20 | 7.0 | 2.6 |
| Example 21 | 6.0 | 2.1 |
| Example 22 | 5.2 | 1.9 |

As can be seen from Table 2, compared with Comparative Example 6, the organic electroluminescence devices of Examples 16 to 18 have a lower voltage at the same luminance (1000 cd/m²), which indicates that the doping of the inert metal Ag in the electron transporting layer is beneficial to the improvement of the mobility of the electron transporting layer and the injection of electrons, and more favorable for balancing the carrier concentration in the organic electroluminescence device, thereby lowering the voltage of the organic electronic device. In addition, the organic electroluminescence devices of Examples 16 to 18 have a higher current efficiency at the same luminance (1000 cd/m²). It indicates that the doping of the inert metal Ag in the electron transporting layer is beneficial to the improvement of the mobility of the electron transporting layer, and the organic electroluminescence device has a more balanced carrier mobility, so that the carriers injected from the two electrodes are effectively recombined in the luminescence region to form excitons, thereby improving the luminescence performance of the organic electroluminescence device.

In addition, the raw material of the electron transporting layer of the organic electroluminescence device in Comparative Example 6 is Bphen-2, and the electron transporting layer further includes an electron injection layer, and the electron injection material is LiF. The electroluminescence performances of the organic electroluminescence devices of Examples 16 to 18 are still superior to that of the organic electroluminescence device in Comparative Example 6, indicating that the presence of the inert metal Ag in the electron transporting layer not only facilitates the electron transporting, but also improves the electron injection, and the electron injection effect of the inert metal Ag is even stronger than that of the electron injection layer using LiF as the raw material.

Moreover, as can be seen from Table 2, as the content of Ag in the electron transporting layer increases, the voltages of the organic electroluminescence devices of Examples 16 to 18 are gradually lowered at 1000 cd/m², and the current efficiency is gradually improved. Furthermore, when the content of Ag reaches 30% by mass, the performance of the organic electroluminescence device is optimal. It is consistent with the test variation of the mobilities of the electron transporting layers of the single carrier devices of Examples 1 to 3 with the doping mass of the inert metal.

Furthermore, it can be seen from the test results of the organic electroluminescence devices of Examples 19 to 22 that, the voltage of the electroluminescence device at the same luminance decreases as the length of the molecular chain of the organic compound increases, which demonstrates that the number of sites that can be coordinated increases as the molecular chain introduced into the compound molecule increases. It is advantageous to reduce the distance between molecules and further close the distance between molecules, and the long-chain structure of the ligand is favorable for constructing a channel for carrier transporting, further improving the mobility, thereby reducing the turn-on voltage of the device.

The technical features of the above-described embodiments may be combined in any combination. For the sake of brevity of description, all possible combinations of the various technical features in the above embodiments are not described. However, as long as there is no contradiction in the combination of these technical features, it should be considered as the scope of the present specification.

1. An electron transporting layer, a raw material of the electron transporting layer comprising an inert metal and an organic compound capable of performing a coordination reaction with the inert metal, the organic compound having the following formula:
Ar₁L₁-Ar₂ₘ-L₂-Ar₃
wherein L₁ and L₂ are respectively independently selected from the group consisting of an alkylene group containing 1 to 12 carbon atoms and an arylene group containing 6 to 30 carbon atoms;
Ar₁, Ar₂, and Ar₃ are respectively independently selected from the group consisting of a nitrogen-oxygen coordination group, a nitrogen-sulfur coordination group, a sulfur-oxygen coordination group, a sulfur-sulfur coordination group, an oxygen-oxygen coordination group, and a nitrogen-nitrogen coordination group; and
m is an integer from 0 to 10.

2. The electron transporting layer according to claim 1, wherein the Ar₁, the Ar₂, and the Ar₃ are respectively independently selected from the group consisting of the following structures: 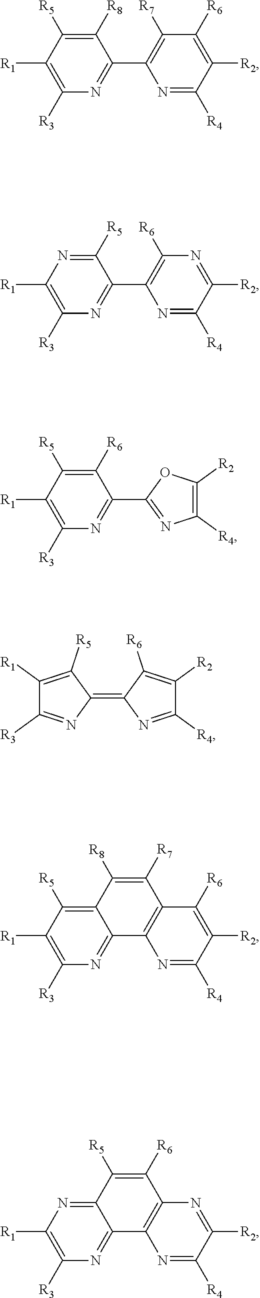 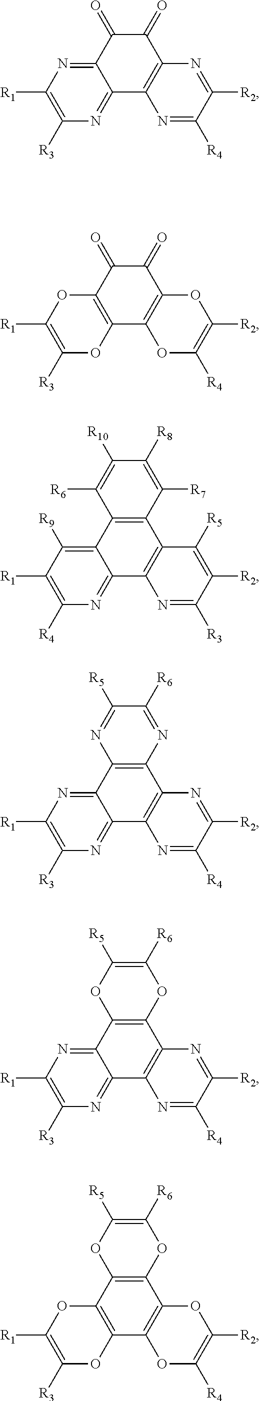 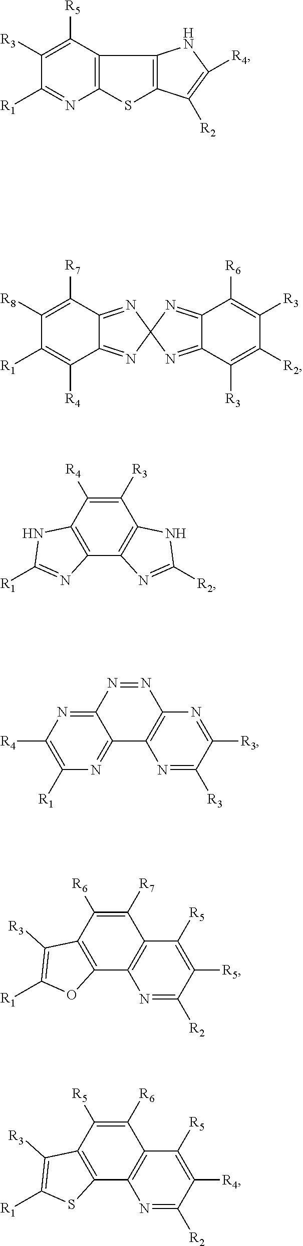 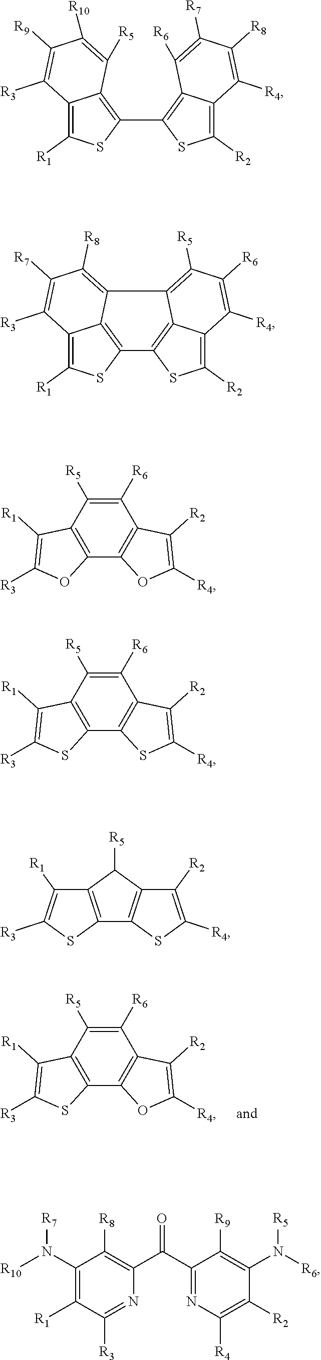
wherein each of R₁, R₂, R₃, R₄, R₅, R₆, R₇, R₈, R₉, and R₁₀ is selected from the group consisting of a hydrogen atom, an alkyl group, an aryl group, a conjugated heterocyclic ring, a methoxy group, an amino group, —CₙH₂ₙ—NH₂, a cyano group, a halogen atom, a haloalkyl group, an aldehyde group, a keto group, an ester group, an acetylacetonate group, —CₙH₂ₙ—CN, —CₙH₂ₙ—COOR, —CₙH₂ₙ—CHO, and —CₙH₂ₙ—COCH₂COR;
R is selected from the group consisting of a hydrogen atom, an alkyl group containing 1 to 10 carbon atoms, and an aryl group containing 6 to 18 carbon atoms; n is an integer from 1 to 30.

3. The electron transporting layer according to claim 2, wherein the aryl group is a phenyl group.

4. The electron transporting layer according to claim 2, wherein sites where R₁, R₂, R₃, and R₄ are located are sites connected to L1 or L2.

5. The electron transporting layer of claim 1, wherein the L1 and the L2 are respectively independently selected from the group consisting of the following structures: 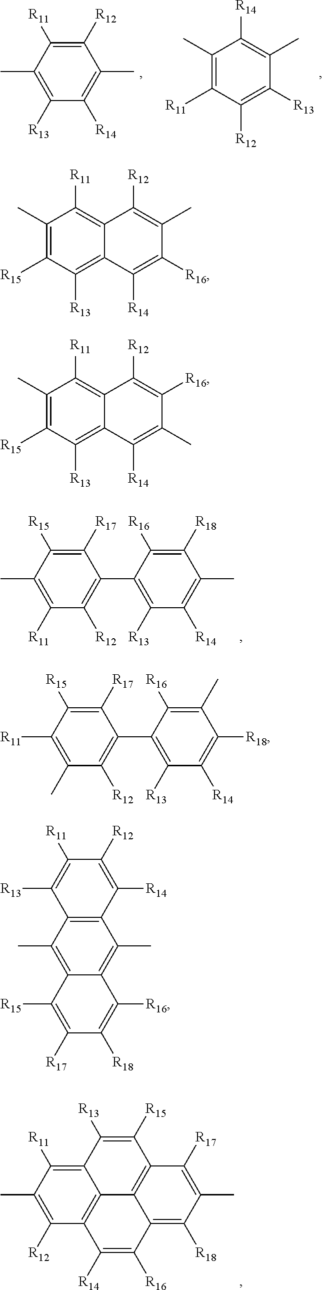
wherein each of R₁₁, R₁₂, R₁₃, R₁₄, R₁₅, R₁₆, R₁₇, and R₁₈ is selected from the group consisting of a hydrogen atom, an alkyl group, a methoxy group, an amino group, —CₙH₂ₙ—NH₂, a cyano group, a halogen atom, a haloalkyl group, an aldehyde group, a keto group, an ester group, and an acetylacetonate group.

6. The electron transporting layer according to claim 1, wherein the organic compound is selected from the group consisting of the following structures:

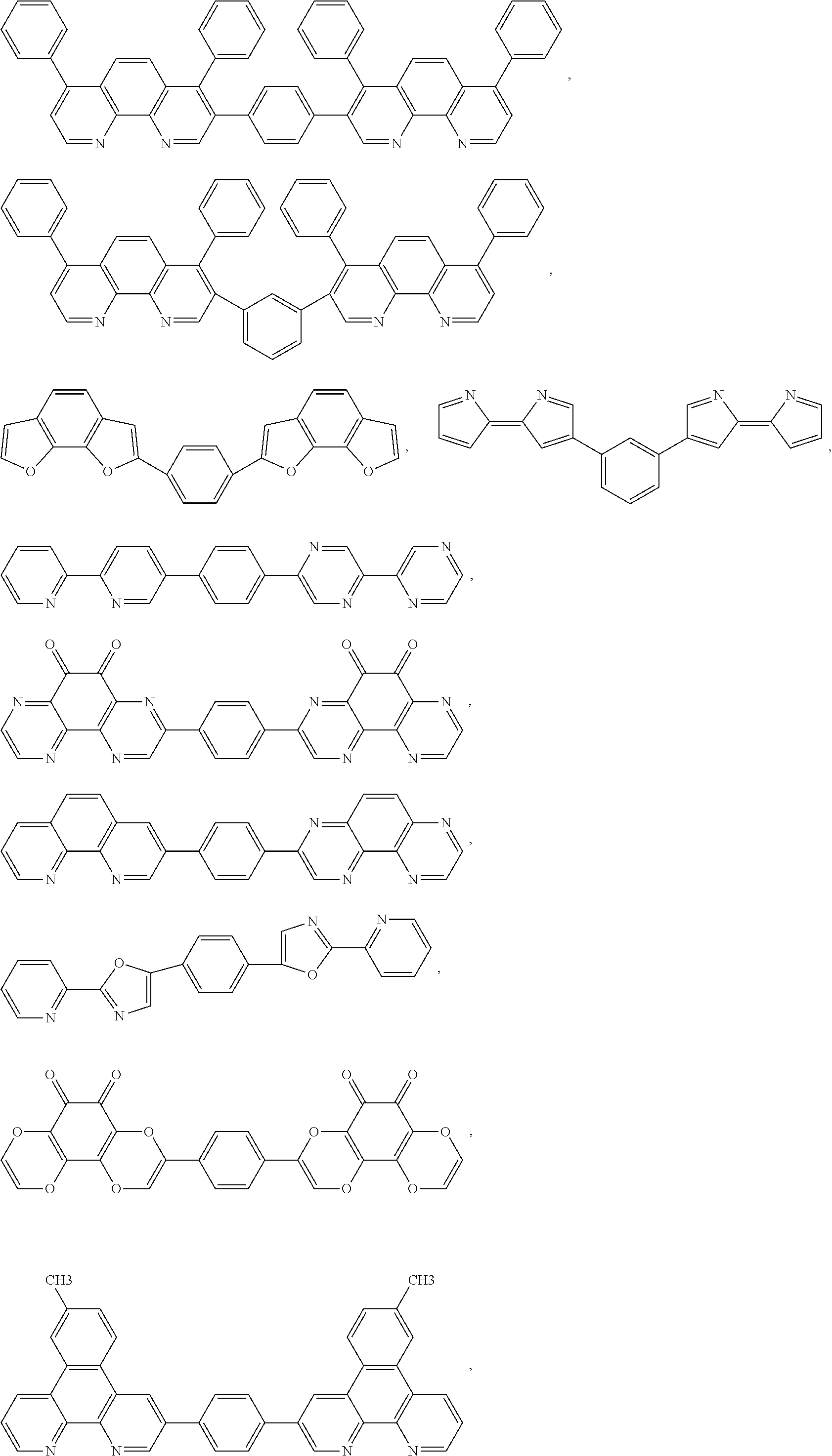

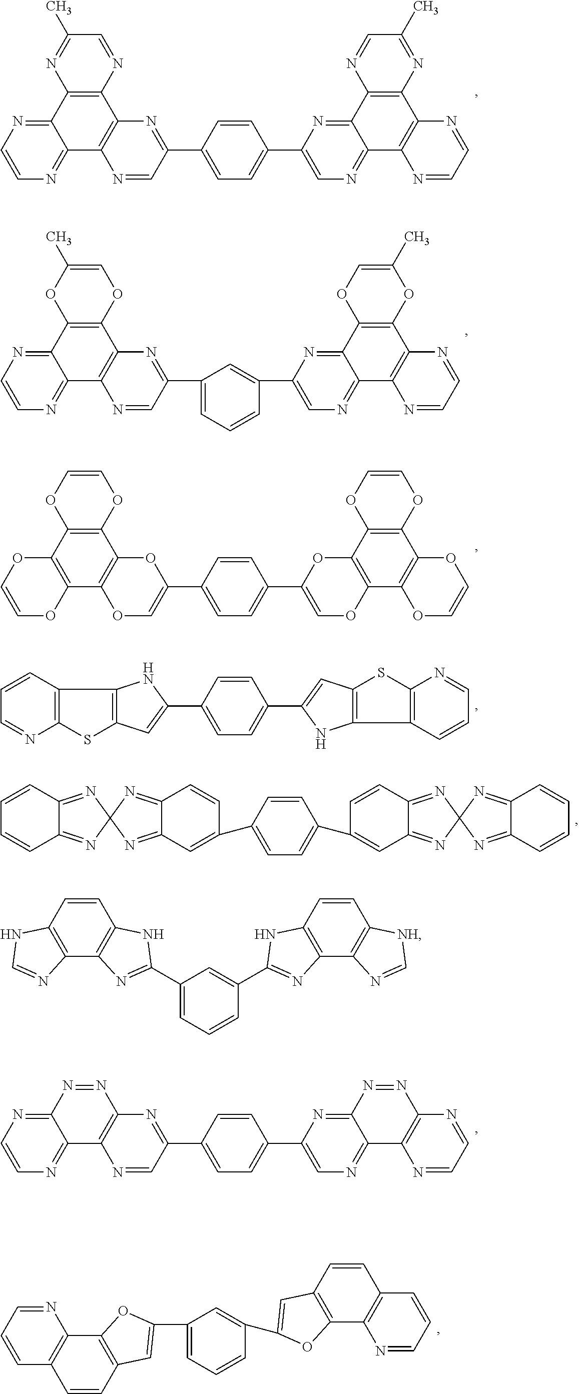

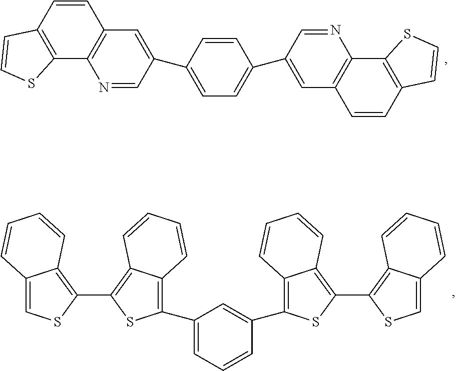 [SMILES: c1cc2ccc3cc(-c4ccc(-c5cnc6c(ccc7ccsc76)c5)cc4)cnc3c2s1 ; c1cc(-c2sc(-c3scc4ccccc34)c3ccccc23)cc(-c2sc(-c3scc4ccccc34)c3ccccc23)c1]

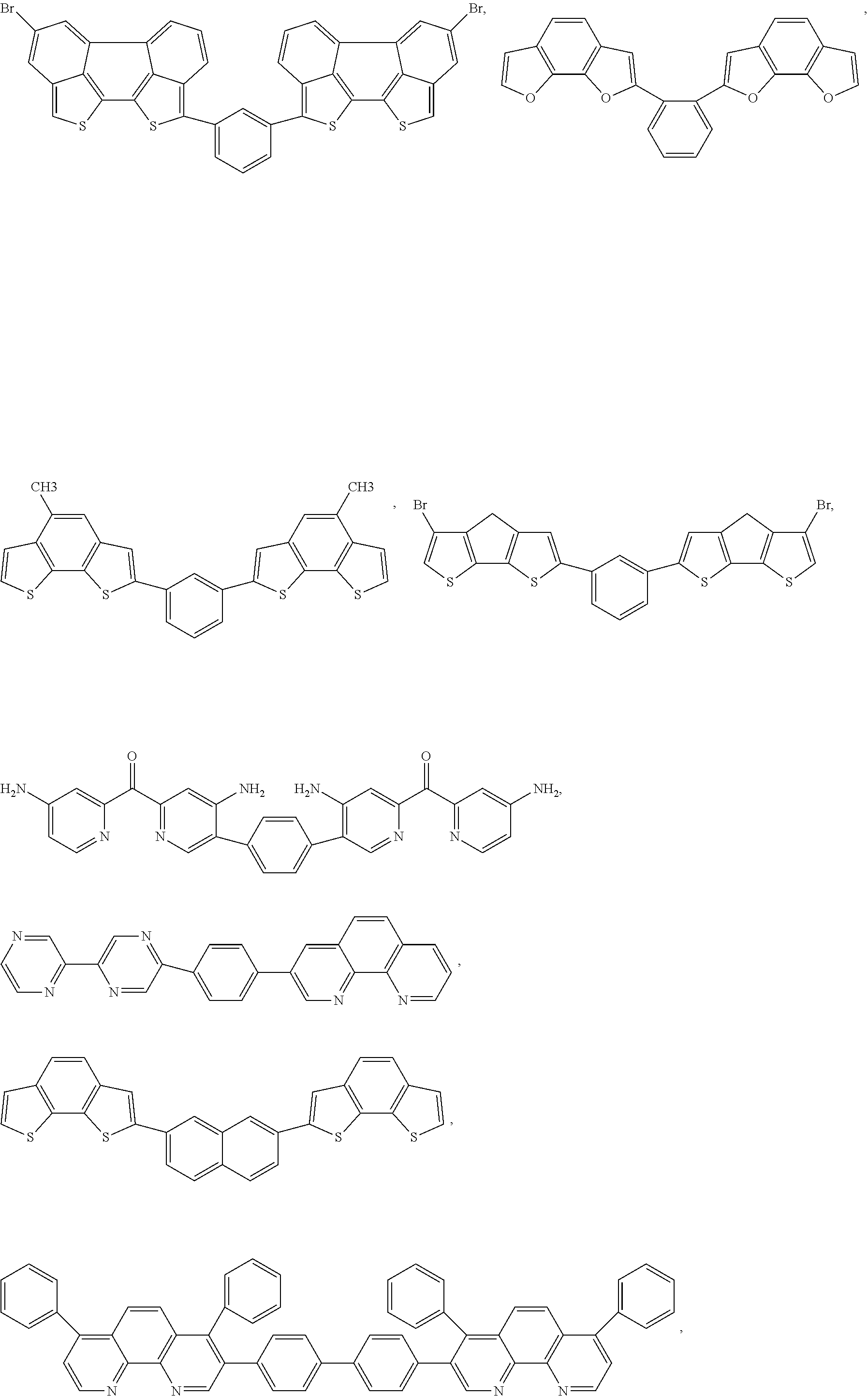

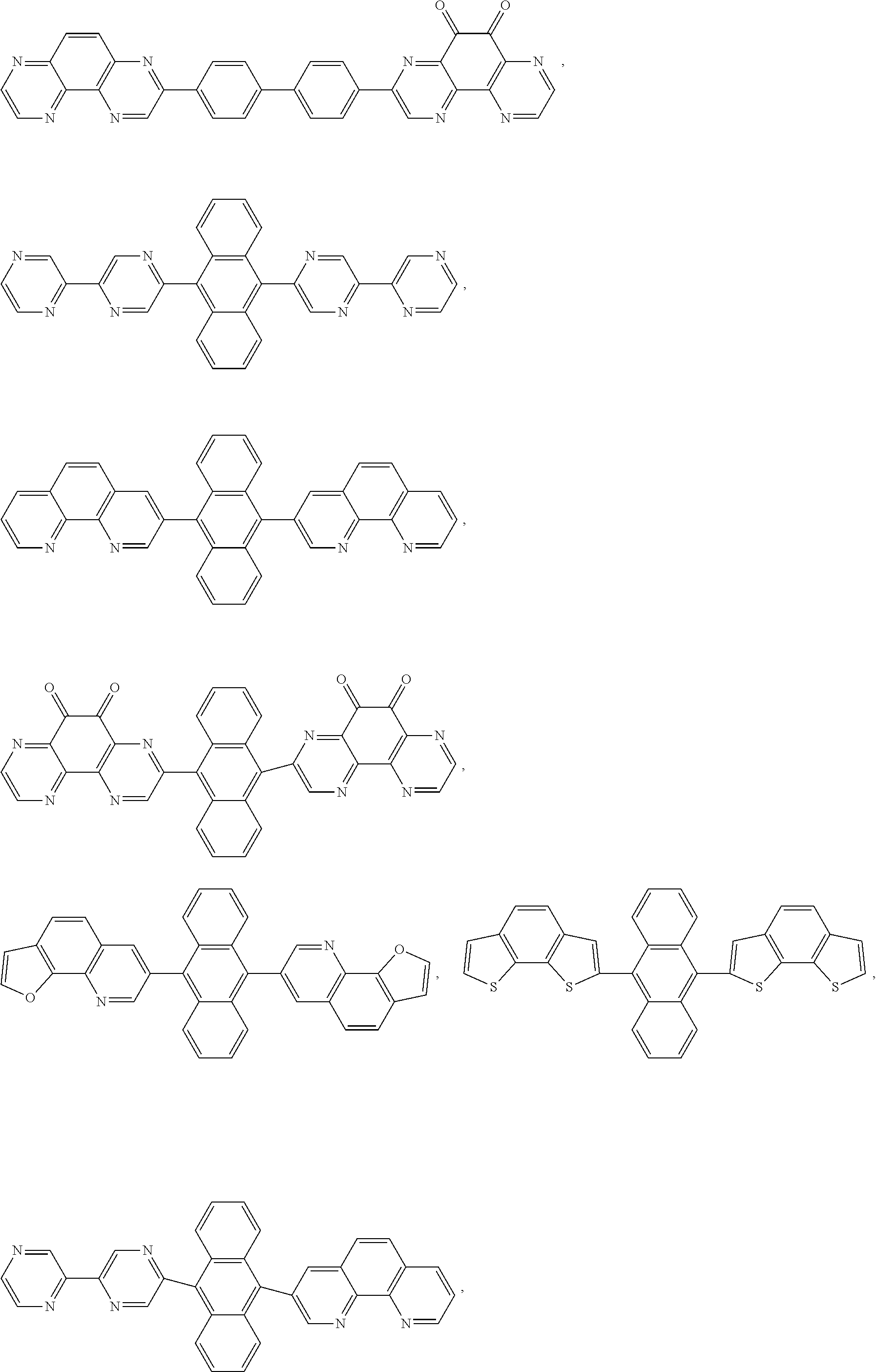

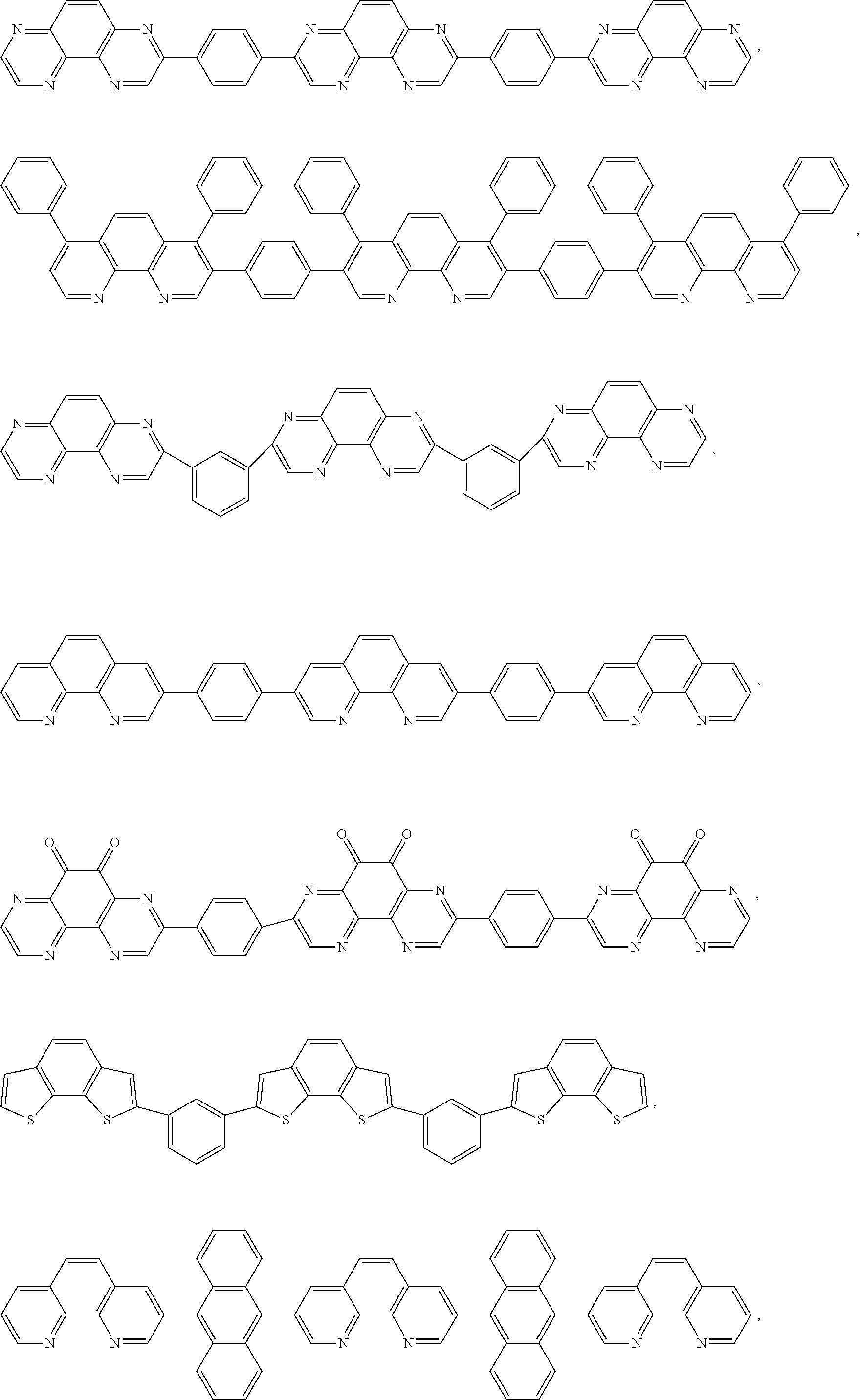

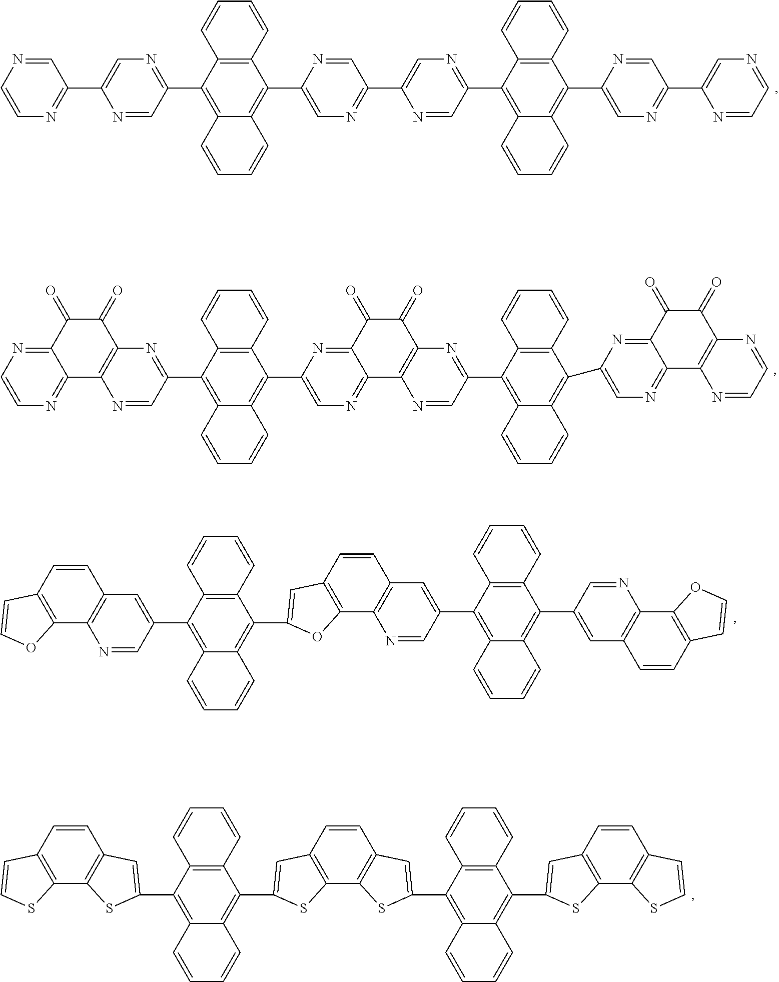 [SMILES: c1ccc2c(-c3cnc(-c4cnc(-c5c6ccccc6c(-c6cnc(-c7cnccn7)cn6)c6ccccc56)cn4)cn3)c3ccccc3c(-c3cnc(-c4cnccn4)cn3)c2c1 ; O=C1C(=O)c2nc(-c3c4ccccc4c(-c4cnc5c(n4)C(=O)C(=O)c4nc(-c6c7ccccc7c(-c7cnc8c(n7)C(=O)C(=O)c7nccnc7-8)c7ccccc67)cnc4-5)c4ccccc34)cnc2-c2nccnc21 ; c1ccc2c(-c3cnc4c(ccc5cc(-c6c7ccccc7c(-c7cnc8c(ccc9ccoc98)c7)c7ccccc67)oc54)c3)c3ccccc3c(-c3cnc4c(ccc5ccoc54)c3)c2c1 ; c1ccc2c(-c3cc4ccc5cc(-c6c7ccccc7c(-c7cc8ccc9ccsc9c8s7)c7ccccc67)sc5c4s3)c3ccccc3c(-c3cc4ccc5ccsc5c4s3)c2c1]

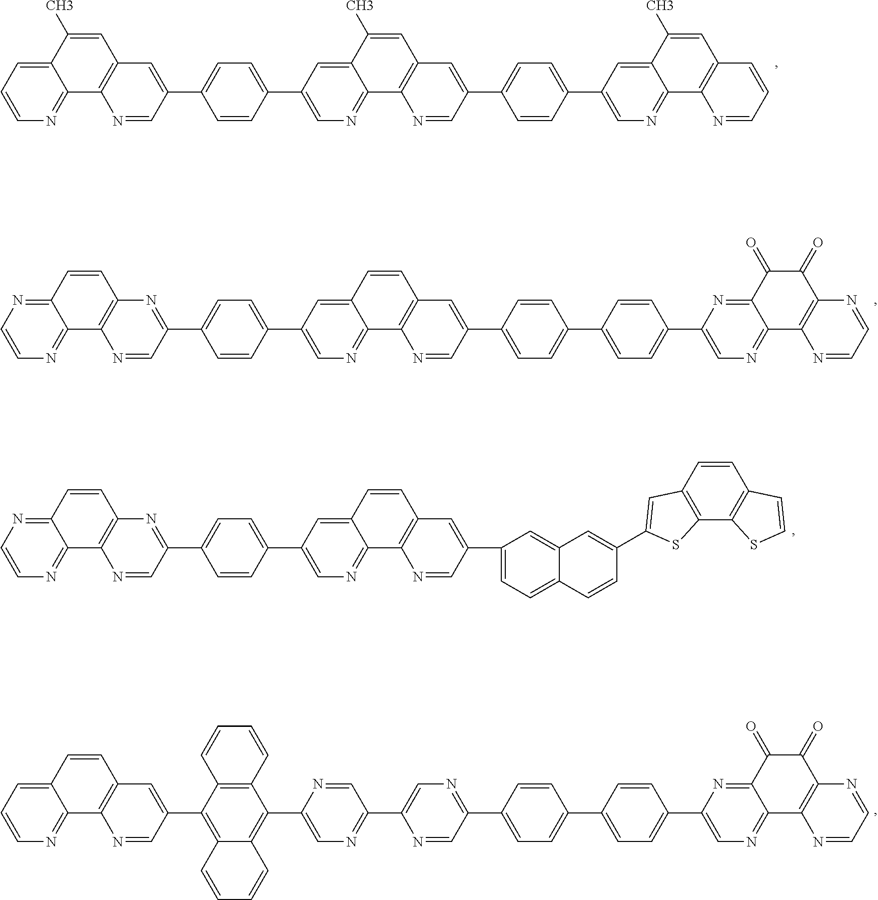 [SMILES: Cc1cc2cc(-c3ccc(-c4cnc5c(c4)c(C)cc4cc(-c6ccc(-c7cnc8c(c7)c(C)cc7cccnc78)cc6)cnc45)cc3)cnc2c2ncccc12 ; O=C1C(=O)c2nc(-c3ccc(-c4ccc(-c5cnc6c(ccc7cc(-c8ccc(-c9cnc%10c(ccc%11nccnc%11%10)n9)cc8)cnc76)c5)cc4)cc3)cnc2-c2nccnc21 ; c1cnc2c(ccc3nc(-c4ccc(-c5cnc6c(ccc7cc(-c8ccc9ccc(-c%10cc%11ccc%12ccsc%12c%11s%10)cc9c8)cnc76)c5)cc4)cnc32)n1 ; O=C1C(=O)c2nc(-c3ccc(-c4ccc(-c5cnc(-c6cnc(-c7c8ccccc8c(-c8cnc9c(ccc%10cccnc%109)c8)c8ccccc78)cn6)cn5)cc4)cc3)cnc2-c2nccnc21]

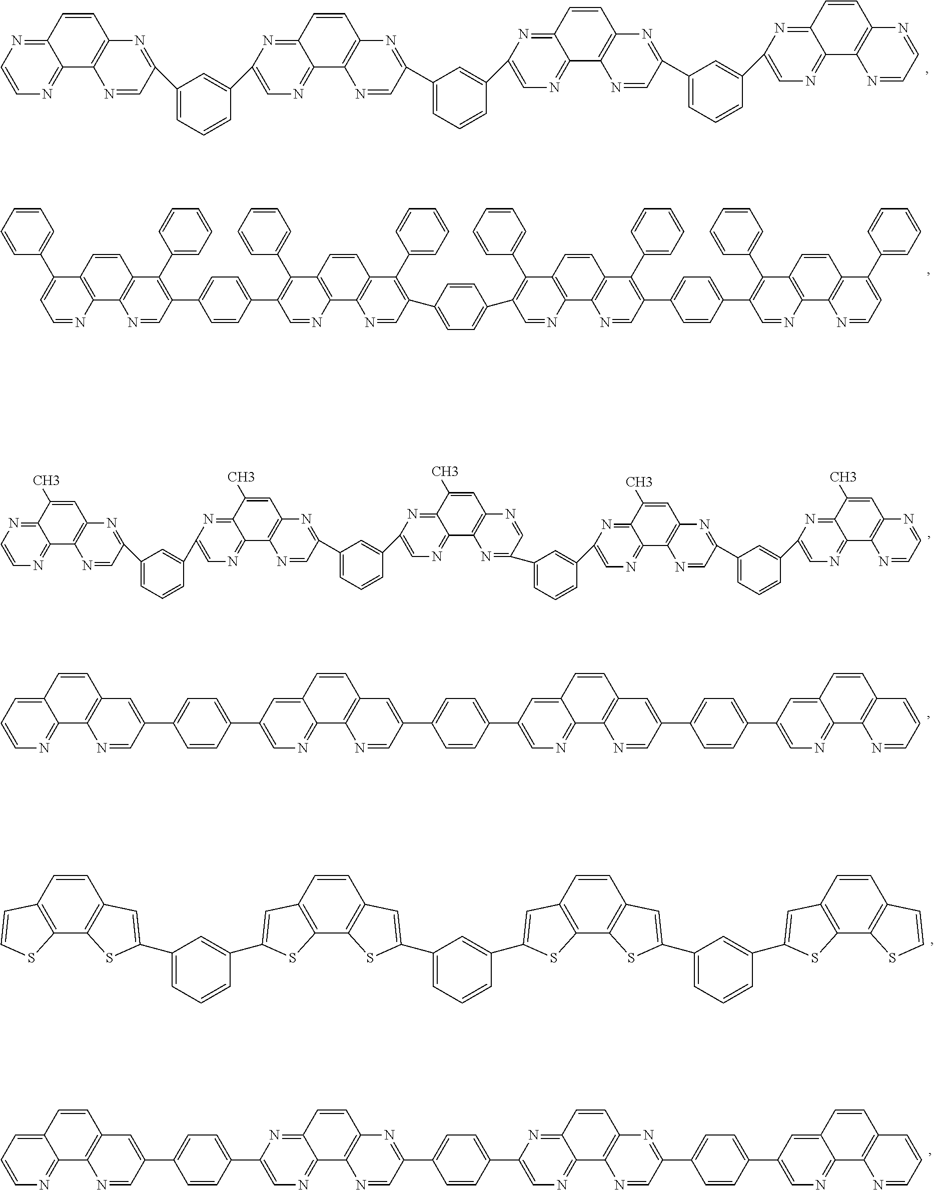

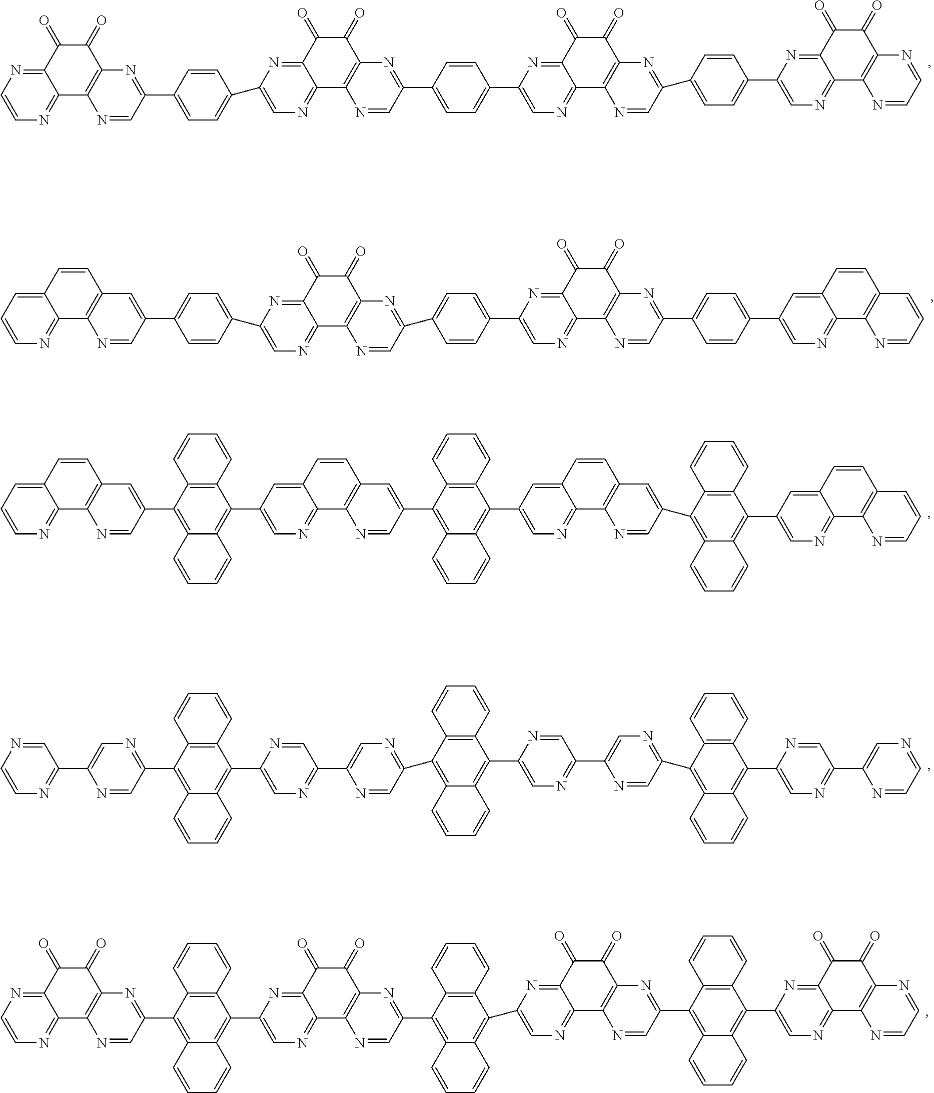

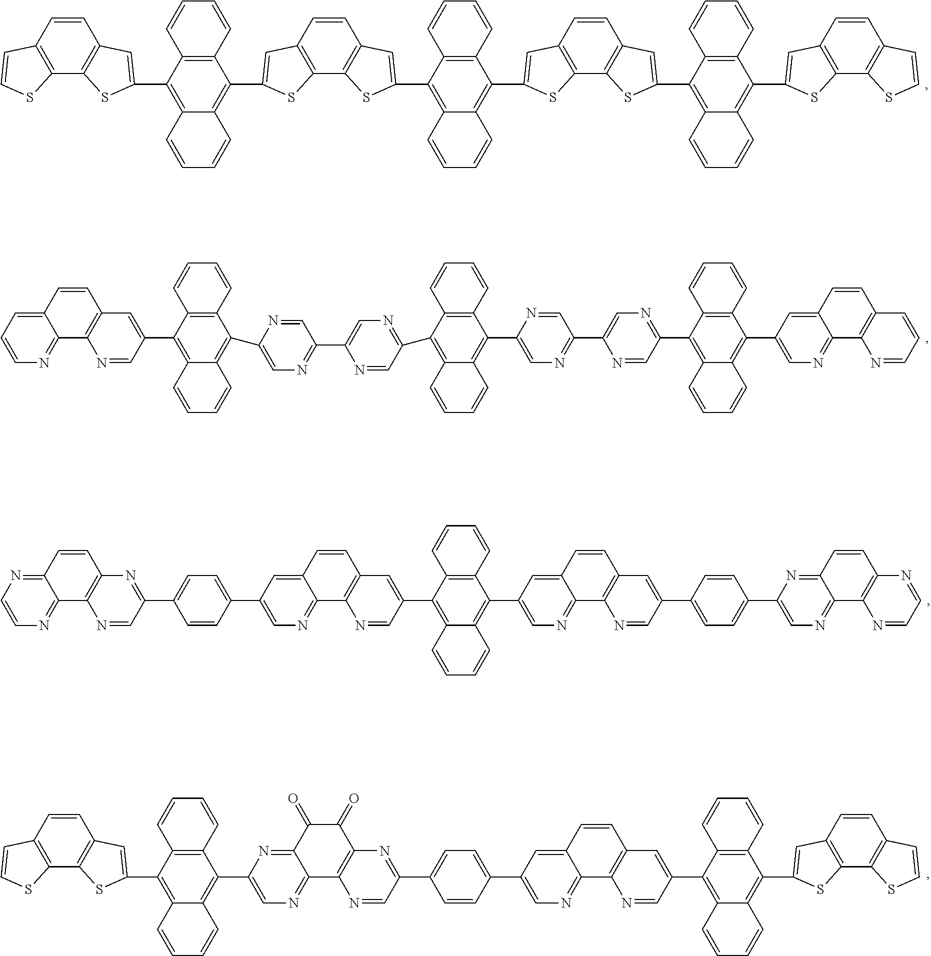

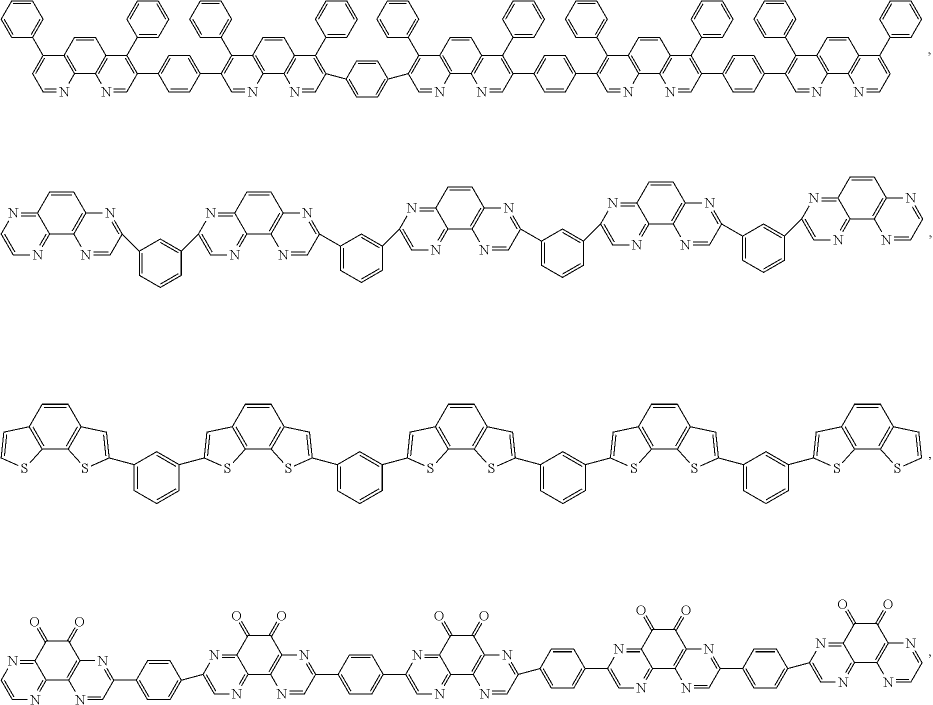

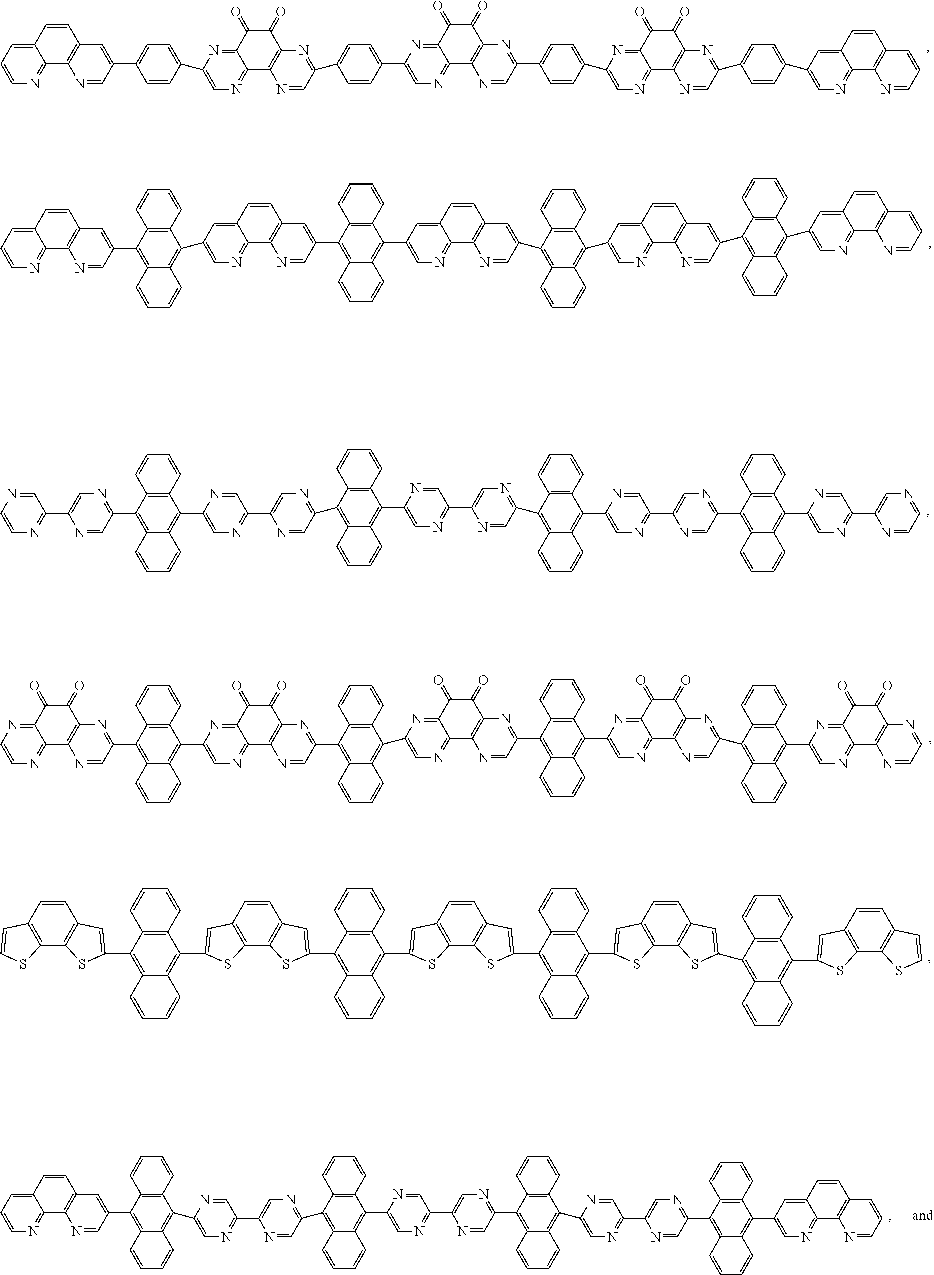

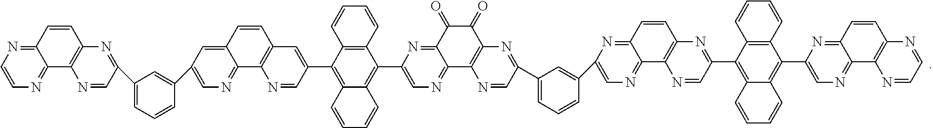 [SMILES: O=C1C(=O)c2nc(-c3c4ccccc4c(-c4cnc5c(ccc6cc(-c7cccc(-c8cnc9c(ccc%10nccnc%109)n8)c7)cnc65)c4)c4ccccc34)cnc2-c2ncc(-c3cccc(-c4cnc5c(ccc6nc(-c7c8ccccc8c(-c8cnc9c(ccc%10nccnc%109)n8)c8ccccc78)cnc65)n4)c3)nc21]

7. The electron transporting layer according to claim 1, wherein the inert metal is at least one selected from the group consisting of titanium, vanadium, chromium, manganese, iron, cobalt, nickel, copper, zinc, zirconium, niobium, molybdenum, technetium, ruthenium, rhodium, lead, silver, cadmium, tantalum, tungsten, rhenium, osmium, iridium, gold, platinum, and mercury.

8. The electron transporting layer according to claim 7, wherein the inert metal is at least one selected from the group consisting of cobalt, nickel, copper, ruthenium, silver, iridium, gold, and platinum.

9. The electron transporting layer according to claim 8, wherein the inert metal is silver.

10. The electron transporting layer according to claim 1, wherein a mass ratio of the inert metal to the organic compound in the raw material of the electron transporting layer ranges from 5:100 to 50:100.

11. An organic electroluminescence device comprising an electron transporting layer according to claim 1.

12. The organic electroluminescence device according to claim 11, wherein the electron transporting layer has a thickness of 1 nm to 200 nm.

13. The organic electroluminescence device according to claim 11, wherein the electron transporting layer has a thickness of 5 nm to 50 nm.

14. The organic electroluminescence device according to claim 11, wherein the organic electroluminescence device comprises a substrate, a first electrode, a hole transporting layer, a luminescence layer, the electron transporting layer, and a second electrode.

15. A display comprising an organic electroluminescence device according to claim 11.
